(19) United States
(12) Patent Application Publication
(10) Pub. No.: US 2026/0023198 A1
(43) Pub. Date: Jan. 22, 2026

(54) LIGHT-ABSORBING COMPOSITION, LIGHT ABSORBER, OPTICAL FILTER, AMBIENT LIGHT SENSOR, IMAGING APPARATUS, LIGHT-ABSORBING COMPOSITION MANUFACTURING METHOD, AND LIGHT ABSORBER MANUFACTURING METHOD

(71) Applicant: Nippon Sheet Glass Company, Limited, Tokyo (JP)

(72) Inventor: Yuichiro KUBO, Tokyo (JP)

(21) Appl. No.: 19/107,499

(22) PCT Filed: Aug. 10, 2023
(86) PCT No.: PCT/JP2023/029380

§ 371 Date: Feb. 27, 2025

(30) Foreign Application Priority Data
Aug. 30, 2022 (JP) 2022-137361

(51) Int. Cl. G02B 5/20; C03C 3/062; C09D 5/32; C09D 7/61; C09D 183/02; G02B 1/04; G02B 1/111; H10F 39/00; H10F 77/40

(52) U.S. Cl. CPC G02B 5/208; C03C 3/062; C09D 5/32; C09D 7/61; C09D 183/02; G02B 1/04; G02B 1/111; C03C 2217/73; G02B 5/206; H10F 39/806; H10F 77/407; H10F 77/413

(57) ABSTRACT

A light-absorbing composition includes a silicon-containing compound α and a light-absorbing compound. The silicon-containing compound α is at least one selected from the group consisting of an alkoxysilane including a group α-1 having 10 or more carbon atoms and a hydrolysate of the alkoxysilane.

### TECHNICAL FIELD

The present invention relates to a light-absorbing composition, a light absorber, an optical filter, an ambient light sensor, an imaging apparatus, a light-absorbing composition manufacturing method, and a light absorber manufacturing method.

### BACKGROUND ART

In imaging apparatuses and ambient light sensors including solid-state image sensing devices such as a charge coupled device (CCD) and a complementary metal oxide semiconductor (CMOS), various types of optical filters are disposed ahead of the solid-state image sensing devices. For example, imaging apparatuses can include optical filters in order to obtain images with good color reproduction. Ambient light sensors can include optical filters in order to adjust sensing of ambient light.

Solid-state image sensing devices generally have sensitivity over a wide wavelength range extending from ultraviolet to infrared regions. On the other hand, the visual sensitivity of humans lies only in a wavelength range from about 380 nm to about 780 nm, which is a so-called visible light region. Hence, a technique is known in which an optical filter for blocking a portion of infrared and ultraviolet light is disposed ahead of a solid-state image sensing device in an imaging apparatus in order to allow the spectral sensitivity of the solid-state image sensing device to approximate to the visual sensitivity of humans.

In particular, light-absorbing-type optical filters including a film or layer including a light absorbent have been attracting attention. The transmittance properties of an optical filter including a film including a light absorbent are less likely to be dependent on the incident angle, and that makes it possible, for example, to obtain a favorable image with a smaller difference in color tone, less uneven in-plane coloring, and high color reproducibility even when light is obliquely incident on the optical filter in an imaging apparatus. Moreover, favorable images are easily obtained using light-absorbing-type optical filters because such optical filters do not include a light-reflecting film and thus can reduce occurrence of ghosting and flare which can be caused by multiple reflection of light. Furthermore, optical filters including a film including a light absorbent are advantageous also in terms of size reduction and thickness reduction of imaging apparatuses.

For example, Patent Literature 1 describes an optical filter including a light-absorbing layer including a copper phosphonate and an organic dye, the optical filter having a thickness of 80 μm or less. The maximum transmittance of the light-absorbing layer of this optical filter in the wavelength range of 750 nm to 1080 nm is 5% or less.

Patent Literature 2 describes an optical filter including a light absorbent formed from a given phosphonic acid and copper ions, the optical filter including a light-absorbing layer free of a given phosphoric acid ester. According to Patent Literature 2, the given phosphoric acid ester is not the best material in terms of weather resistance because of its high hydrolyzability.

Patent Literature 3 describes an optical filter including an UV-IR absorbing layer including an UV-IR absorbent formed from copper ions and at least one acid selected from a phosphonic acid and a sulfonic acid, the UV-IR absorbent being capable of absorbing ultraviolet and infrared light. This optical filter has a haze of 5% or less. According to Patent Literature 3, it is possible to obtain high-quality images with an imaging apparatus in which the above optical filter including the above UV-IR absorbing layer is embedded.

### CITATION LIST

### Patent Literature

Patent Literature 1: WO 2020/071461 A1

Patent Literature 2: WO 2019/093076 A1

Patent Literature 3: WO 2019/208518 A1

### SUMMARY OF INVENTION

### Technical Problem

The techniques described in Patent Literatures 1 to 3 leave room for further study in terms of slimness and optical properties. Therefore, the present invention provides a light-absorbing compound advantageous in terms of slimness and optical properties. The present invention also provides a light absorber advantageous in terms of slimness and optical properties.

### Solution to Problem

The present invention provides a light-absorbing composition including:
at least one selected from the group consisting of an alkoxysilane including a group having 10 or more carbon atoms, a hydrolysate of the alkoxysilane, and a polymerization product of a hydrolysate of the alkoxysilane; and
a light-absorbing compound.

The present invention also provides a light absorber
having an average T^{A}₄₆₀₋₆₀₀ of 80% or more, where the average T^{A}₄₆₀₋₆₀₀ is an average transmittance in a wavelength range of 460 nm to 600 nm in a transmission spectrum obtained by allowing light to be incident on the light absorber at an incident angle of 0°, and
satisfying requirements 0.009≤η₃₈₀ and 0.008≤η₇₅₀, where a value determined by dividing an optical density OD of the light absorber at a wavelength λ by a thickness of the light absorber is expressed as η_{λ}[μm⁻¹].

The present invention also provides an optical filter including the above light absorber.

The present invention also provides an ambient light sensor including the above light absorber.

The present invention also provides an imaging apparatus including the above light absorber.

The present invention also provides a light-absorbing composition manufacturing method including:
producing a light-absorbing compound dispersion where a light-absorbing compound including a phosphonic acid and a copper component is dispersed in a solvent;
mixing the light-absorbing compound dispersion with an alkoxysilane including a group having 10 or more carbon atoms or a hydrolysate of the alkoxysilane; and
removing a portion of the solvent from the light-absorbing compound dispersion.

The present invention also provides a light absorber manufacturing method including:
solidifying a light-absorbing composition applied to a surface of a substrate to give a light absorber, wherein
the light-absorbing composition includes:
a light-absorbing compound including a phosphonic acid and a copper component; and
at least one selected from the group consisting of an alkoxysilane including a group having 10 or more carbon atoms, a hydrolysate of the alkoxysilane, and a polymerization product of a hydrolysate of the alkoxysilane, and
the light absorber has a thickness of 150 μm or less.

The present invention also provides an optical filter including:
a light absorber; and
an antireflection film provided on a surface of the light absorber, wherein
the optical filter satisfies the following requirements (I) and (II):
   (I) 0.009≤η₂₋₃₈₀ and 0.008≤η₂₋₇₅₀, where a value determined by dividing an optical density OD at a wavelength λ by a thickness of the light absorber is expressed as η_{2-λ}[μm⁻¹]; and
   (II) 90%≤T₂^{A}₄₆₀₋₆₀₀, where T₂^{A}₄₆₀₋₆₀₀ is an average transmittance in a wavelength range of 460 nm to 600 nm.

### ADVANTAGEOUS EFFECTS OF INVENTION

The above light-absorbing composition and the above light absorber are advantageous in terms of slimness and optical properties.

### BRIEF DESCRIPTION OF DRAWINGS

FIG. 1A is a cross-sectional view showing an example of an optical filter according to the present invention.

FIG. 1B is a cross-sectional view showing another example of the optical filter according to the present invention.

FIG. 1C is a cross-sectional view showing yet another example of the optical filter according to the present invention.

FIG. 1D is a cross-sectional view showing yet another example of the optical filter according to the present invention.

FIG. 2 is a graph showing a transmission spectrum of a glass included in a substrate.

FIG. 3A is a cross-sectional view showing an example of an ambient light sensor according to the present invention.

FIG. 3B is a cross-sectional view showing an example of a photoelectric conversion element according to the present invention.

FIG. 4A shows an example of an imaging apparatus according to the present invention.

FIG. 4B shows another example of the imaging apparatus according to the present invention.

FIG. 5A is a graph showing a transmission spectrum of a light absorber according to Example 1.

FIG. 5B is a graph showing a reflection spectrum of the light absorber according to Example 1.

FIG. 6A is a graph showing a transmission spectrum of a light absorber according to Example 2.

FIG. 6B is a graph showing a reflection spectrum of the light absorber according to Example 2.

FIG. 7A is a graph showing a transmission spectrum of a light absorber according to Example 3.

FIG. 7B is a graph showing a reflection spectrum of the light absorber according to Example 3.

FIG. 8 is a graph showing a transmission spectrum of a light absorber according to Example 8.

FIG. 9 is a graph showing a transmission spectrum of a light absorber according to Example 13.

FIG. 10 is a graph showing a transmission spectrum of a light absorber according to Example 14.

FIG. 11A is a graph showing a transmission spectrum of a substrate according to Example 16.

FIG. 11B is a graph showing a transmission spectrum of an optical filter according to Example 16.

FIG. 12 is a graph showing a transmission spectrum of an optical filter according to Comparative Example 3.

FIG. 13 is a graph showing a transmission spectrum of an optical filter according to Example 17.

FIG. 14 is a graph showing a transmission spectrum of an optical filter according to Example 18.

### DESCRIPTION OF EMBODIMENTS

Thickness reduction is increasingly required of optical filters to be mounted in cameras and ambient light sensors due to worldwide prevalence of information terminals, such as smartphones, equipped with camera modules. Although the optical filter described in Patent Literature 1 has a thickness of 80 μm or less and a transmittance of 5% or less in the wavelength range of 750 nm to 1080 nm, the light absorption properties thereof in this wavelength range are insufficient. From this fact, it is understood that when the optical filter has a thickness of around 110 μm, it is hard for the optical filter to achieve, for example, a transmittance of 1% or less in the wavelength range of 750 nm to 1080 nm. In other words, it is understood that it is hard for an optical filter that is as slim as around 110 μm and that includes a light-absorbing layer including a copper phosphonate and an organic dye to achieve sufficient light absorption performance even in combination with the organic dye.

The optical filter described in Patent Literature 2 is promising in that the optical filter is free of a phosphoric acid ester; however, in terms of achieving both slimness and desired optical properties, it is difficult to say that the optical filter has sufficient properties. Additionally, the lack of a phosphoric acid ester may cause aggregation of a portion of the copper phosphonate to decrease the transmittance in the visible region.

Patent Literature 3 describes the content of a copper component included in a light-absorbing compound and the viscosity of a liquid light-absorbing composition being a precursor of the UV-IR absorbing layer. The haze value of the UV-IR absorbing layer described in Patent Literature 1 is at least 0.2%. If a light-absorbing-type optical filter can achieve a haze less than 0.2%, the optical filter can have higher value.

As a result of intensive studies, the present inventor has found a new light-absorbing compound that is, albeit slim, advantageous in achieving desired optical properties such as transmittances corresponding closely to a human visual sensitivity curve and a low haze. Moreover, the present inventor has completed a new light absorber that is advantageous in achieving desired optical properties such as transmittances corresponding closely to a human visual sensitivity curve and a low haze.

Embodiments of the present invention will be described hereinafter. The following description relates to examples of the present invention, and the present invention is not limited to the embodiments given below.

The light-absorbing composition includes a silicon-containing compound α and a light-absorbing compound. The silicon-containing compound α is at least one selected from the group consisting of an alkoxysilane including a group α-1 having 10 or more carbon atoms, a hydrolysate of the alkoxysilane, and a polymerization product of a hydrolysate of the alkoxysilane. The hydrolysate of the alkoxysilane is a silicon compound including a silanol group (—Si—OH) resulting from hydrolysis of the alkoxysilane.

The polymerization product of the hydrolysate of the alkoxysilane is a compound including a siloxane bond (—O−Si—O—) resulting from polycondensation of a portion of the hydrolysate. It is thought that because of the presence of the silicon-containing compound α, the group a-1 tends to experience steric hindrance in aggregation of the light-absorbing compound. Therefore, for example, formation of an aggregate of the light-absorbing compound is likely to be prevented in formation of the light-absorbing compound including a structure of a complex. This makes it likely that the light-absorbing compound is uniformly dispersed in the light-absorbing composition and that a light absorber produced using the light-absorbing composition achieves desired optical properties such as a transmission spectrum corresponding to a human visual sensitivity curve and a low haze. The alkoxysilane including the group α-1 is represented, for example, by the following formula (1). In the formula (1), n is 1, 2, or 3, R¹¹ is a group including at least a carbon atom (C) and a hydrogen atom (H), and at least one R¹¹ is the group α-1 having 10 or more carbon atoms. The symbol R¹² is a group including at least a carbon atom (C) and a hydrogen atom (H). The symbol R¹² may be the same as R¹¹, or may be different from R¹¹.

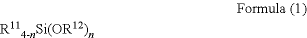

The light-absorbing compound is not limited to a particular compound. The light-absorbing compound may be, for example, a compound including a phosphonic acid and a copper component, a compound including a phosphoric acid ester and a copper component, and a compound including another phosphoric acid compound and a copper component. Examples of the other phosphoric acid compound include phosphoric acid, phosphorous acid, and phosphinic acid. A phosphoric acid-including compound may be a phosphoric acid-copper complex represented by MₓCu_{y}PO_{z} (where M may be absent or represents a metal element other than Cu, and x, y, and z are each a real number). When the light-absorbing compound including the phosphoric acid compound, such as the phosphonic acid, the phosphoric acid ester, or phosphoric acid, and the copper component is generated, the light-absorbing compound may include a portion of anions of a compound being a raw material of the copper component, especially copper ions. For example, when the raw material of the copper component is copper acetate, the light-absorbing compound may include a portion of an acetic acid component; when the raw material of the copper component is copper benzoate, the light-absorbing compound may include a portion of a benzoic acid component. Inclusion of the phosphoric acid compound, such as the phosphonic acid, the phosphoric acid ester, or phosphoric acid, and the copper component in the light-absorbing compound does not prevent the light-absorbing compound from including a compound or an element other than these. The light-absorbing compound may be: a compound including a sulfonic acid and a copper component; a metal oxide; or an organic dye. Examples of the metal oxide include tungsten oxide, indium tin oxide (ITO), and antimony tin oxide. Examples of the organic dye include a diimmonium-based compound, a cyanine-based compound, a squarylium-based compound, a phthalocyanine-based compound, and a pyrrolopyrrole-based compound.

The light-absorbing compound is desirably a compound including a phosphonic acid and a copper component, a compound including a phosphoric acid ester and a copper component, a compound including phosphoric acid and a copper component, a compound including a sulfonic acid and a copper component, or any of these compounds formed as complexes. In this case, the light-absorbing compound is likely to have a broad absorption band in the infrared region, and the light-absorbing composition is promising as a material of a filter capable of achieving blocking of light in a given wavelength range only by means of an absorption action.

In the light-absorbing composition, one of the above compounds may be used alone as the light-absorbing compound, or a plurality of the above compounds may be used in combination as the light-absorbing compound.

A phosphonic acid, a phosphoric acid ester, and phosphoric acid are each an oxide including a phosphorus atom (P) and an oxygen atom (O). These three may coexist in the light-absorbing compound; for example, the light-absorbing compound may be present as a compound including a phosphonic acid, a phosphoric acid ester, and a copper component. When the light-absorbing compound is a complex including a phosphonic acid and a copper component, a phosphoric acid ester may be added as a dispersant. In this case, the light-absorbing composition may include a compound including a phosphonic acid, a phosphoric acid ester, and a copper component. Copper (II) acetate or copper (II) benzoate can be a raw material of the copper component of the light-absorbing compound. In this case, in the light-absorbing compound, a portion of an acetic acid component (CH₃COO⁻ or CH₃COOH) or a benzoic acid component (C₆H₅COO⁻ or C₆H₅COOH) included in the raw material may be coordinated to a copper ion or a copper complex including the phosphorus compound, such as a phosphonic acid, and the copper component. Furthermore, a copper compound being a raw material of the copper component may be a hydrate, or a raw material of the copper component may include a water molecule.

When the light-absorbing compound includes a phosphonic acid, the phosphonic acid is not limited to a particular phosphonic acid. The phosphonic acid is represented, for example, by the following formula (a). In the formula (a), R₁ is an alkyl group or an alkyl halide group in which at least one hydrogen atom in an alkyl group is substituted with a halogen atom. In this case, a transmission band of a light absorber produced using the light-absorbing composition is likely to extend to a wavelength around 700 nm, and the light absorber is likely to have desired transmittance properties. The phosphonic acid represented by the formula (a) is called “alkylphosphonic acid”.

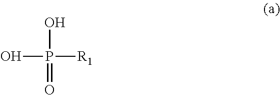

The alkylphosphonic acid is, for example, methylphosphonic acid, ethylphosphonic acid, normal(n-)propylphosphonic acid, isopropylphosphonic acid, normal(n-)butylphosphonic acid, isobutylphosphonic acid, sec-butylphosphonic acid, tert-butylphosphonic acid, hexylphosphonic acid, octylphosphonic acid, or bromomethylphosphonic acid.

As the phosphonic acid, the light-absorbing compound may include a phosphonic acid represented by the following formula (b). In the formula (b), R₂ is an aryl group, an aryl halide group in which at least one hydrogen atom in an aryl group is substituted with a halogen atom, a group in which at least one hydrogen atom in an aryl group is substituted with a nitro group, or a group in which at least one hydrogen atom in an aryl group is substituted with a hydroxy group. The aryl group is, for example, a phenyl group. The aryl halide group is, for example, a phenyl halide group. In this case, a light absorber produced using the light-absorbing composition is more likely to have desired transmittance properties. The phosphonic acid represented by the formula (b) is called “arylphosphonic acid”.

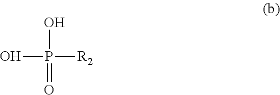

The arylphosphonic acid is, for example, phenylphosphonic acid, bromophenylphosphonic acid, benzylphosphonic acid, fluorophenylphosphonic acid, iodophenylphosphonic acid, nitrophenylphosphonic acid, hydroxyphenylphosphonic acid, tolylphosphonic acid, xylylphosphonic acid, or naphthylphosphonic acid.

As the phosphonic acid, the light-absorbing compound may include only the alkylphosphonic acid, only the arylphosphonic acid, or both the alkylphosphonic acid and the arylphosphonic acid. The light-absorbing compound may include one alkylphosphonic acid or two or more alkylphosphonic acids. The light-absorbing compound may include one arylphosphonic acid or two or more arylphosphonic acids. In the light-absorbing compound, the alkylphosphonic acid and the arylphosphonic acid may each be bonded to the copper component.

When the light-absorbing compound includes the copper component, the concept of the copper component includes copper ions, a copper complex, a copper-including compound, and the like. The copper component can have high absorption properties in terms of a portion of light belonging to a near-infrared region and a high transmittance from 450 nm to 680 nm within the visible region. For example, roughly speaking, when having a six-coordinate complex structure, a divalent copper ion Cu²⁺ absorbs light with a wavelength having energy commensurate with energy associated with electron transition between d orbitals having different energy levels. Since a divalent copper ion absorbs light belonging to infrared light and having wavelengths in a relatively broad range, a divalent copper ion is thought to exhibit a highly useful light absorption function when included in a filter used in the field of digital photography. The width of an absorption band, the absorption intensity, and the like largely depend on the structure or properties of a ligand coordinated to a copper ion. Because of these circumstances, it is desirable that a light absorber or an optical filter including the phosphorus compound, such as the phosphonic acid and/or the phosphoric acid ester, including a compound to which a copper ion is coordinated be used for correction for the visual sensitivity.

A supply source of the copper component included in the light-absorbing compound is not limited to a particular substance. The supply source of the copper component may be, for example, a copper salt anhydride or copper salt hydrate, such as copper acetate, copper benzoate, copper pyrophosphate, or copper stearate, of an organic acid, or a mixture thereof. Among these, copper acetate or copper benzoate is desirably used. One of these copper salts may be used alone, or two or more of these copper salts or a mixture thereof may be used.

The light-absorbing composition may include a silicon-containing compound β being at least one selected from the group consisting of an alkoxysilane represented by the following formula (2) and a hydrolysate of the alkoxysilane. In the formula (2), m is an integer of 3 or 4, R⁰¹ and R⁰² may be the same or different from each other, R⁰¹ and R⁰² are each a group including at least a carbon atom (C) and a hydrogen atom (H). The alkoxysilane represented by the formula (2) is a trifunctional alkoxysilane or a tetrafunctional alkoxysilane. As the silicon-containing compound β, the light-absorbing composition may include only a trifunctional alkoxysilane, may include only a tetrafunctional alkoxysilane, or may include both a trifunctional alkoxysilane and a tetrafunctional alkoxysilane. The silicon-containing compound may be the alkoxysilane as a monomer, or may be a compound formed by hydrolysis of a portion of the alkoxysilane. The silicon-containing compound β may include a compound including a siloxane bond resulting from polycondensation of a portion of a hydrolysate of the alkoxysilane.

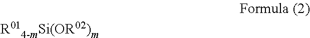

Since the light-absorbing composition includes the silicon-containing compound β represented by the formula (2), a network is likely to be formed during solidification of the light-absorbing composition. For example, in the case of manufacturing a light absorber using the light-absorbing composition, a siloxane bond (—Si—O—Si—) is formed by a treatment for a sufficient hydrolysis reaction and a sufficient polycondensation reaction of the alkoxysilane. This makes it likely that the light absorber has high humidity resistance. This also imparts high thermal resistance to the light absorber. The reason is that a siloxane bond is chemically stable owing to its high binding energy and is excellent in thermal resistance and humidity resistance, compared to, for example, a —C— C-bond and a —C—O-bond. In terms of improving the density of the light absorber, the light-absorbing composition desirably includes, as the silicon-containing compound β, the tetrafunctional alkoxysilane represented by the formula (2) where m=4 is established. R₀₁ and R₀₂ may each be a hydrocarbon group having 1 to 8 carbon atoms, or may each be a group including an aryl group. Flexibility can be imparted to the light absorber by including the trifunctional alkoxysilane represented by the formula (2) where m=3 is established in addition to the tetrafunctional alkoxysilane represented by the formula (2) where m=4 is established.

As described above, the light-absorbing composition includes the silicon-containing compound α as one of the above silicon-containing compounds. The group α-1 in the silicon-containing compound α is not limited to a particular group as long as having 10 or more carbon atoms. The group α-1 may be an alkyl group, or may be a substituted alkyl group in which at least one hydrogen atom in an alkyl group is substituted with a halogen atom, a nitro group, or an amino group. In this case, the alkyl group and the substituted alkyl group may have a branched carbon chain or may be free of a branched carbon chain.

The group α-1 may have a phenyl group, or may be a substituted phenyl group in which at least one hydrogen atom in a phenyl group is substituted with a halogen atom, a nitro group, or an amino group. The group α-1 may have a reactive functional group such as a vinyl group, an epoxy group, a carbonyl group, an ester group, an amino group, a nitrile group, or a hydroxy group.

The silicon-containing compound α may be a trifunctional alkoxysilane, a bifunctional alkoxysilane, or a hydrolysate of either of these alkoxysilanes. These compounds make it easy to disperse the light-absorbing compound in a desired state in the light-absorbing composition, and can impart a given flexibility and a given crosslinkability to a polymer generated by hydrolysis and polycondensation of a tetrafunctional alkoxysilane such as tetraethoxysilane (TEOS). These facts are advantageous in terms of improvement of mechanical strength and weather resistance of a light absorber obtained using the light-absorbing composition.

When the light-absorbing composition includes the trifunctional alkoxysilane, the bifunctional alkoxysilane, or the hydrolysate of either of these alkoxysilanes as the silicon-containing compound α, it is possible to make it less necessary for the light-absorbing composition to include a compound, such as a polyoxyalkylphosphoric acid ester, for imparting dispersibility.

As the silicon-containing compound α, the light-absorbing composition may include only at least one selected from the group consisting of the trifunctional alkoxysilane and the hydrolysate of the trifunctional alkoxysilane. As the silicon-containing compound α, the light-absorbing composition may include only at least one selected from the group consisting of the bifunctional alkoxysilane and the hydrolysate of the bifunctional alkoxysilane. The light-absorbing composition may include the bifunctional alkoxysilane, the trifunctional alkoxysilane, or the hydrolysate of either of these each being the silicon-containing compound α, together with the tetrafunctional or trifunctional alkoxysilane represented by the formula (2) or the hydrolysate of either of these.

The light-absorbing composition may be free of a curable resin. The reason is that the silicon-containing compound α allows the light-absorbing compound to be present in a desired state and is polymerized so as to solidify the light-absorbing composition or that the silicon-containing compound β functions as a network former and is polymerized so as to solidify the light-absorbing composition. When the light-absorbing composition includes the tetrafunctional alkoxysilane included in the alkoxysilane represented by the formula (2), improvement of the density or hardness of a light absorber is expected. The alkoxysilanes represented by the formulae (1) and (2) can be increased in molecular weight and solidified by hydrolysis and polycondensation of a siloxane bond by what is called a sol-gel process. Alternatively, the light-absorbing composition may be solidified into a dried gel by removing a solvent or a by-product included in the light-absorbing composition including the alkoxysilane or the hydrolysate thereof by evaporation or the like. A dominant effect cannot be determined unambiguously, but various effects and processes including the dispersing effect of the light-absorbing compound are thought to be included.

A content of the silicon-containing compound α in the light-absorbing composition is not limited to a particular value. For example, in the case where the light-absorbing compound includes the copper component, a ratio rcs of an amount of silicon atoms included in the silicon-containing compound α to an amount of the copper component is 0.30 or more on a molar basis. In this case, an aggregate of the light-absorbing compound is much less likely to be formed in the light-absorbing composition. The ratio rcs is desirably 0.35 or more, more desirably 0.40 or more. The ratio r_{CS} is, for example, 2.80 or less. In this case, it is easy to reduce the thickness of a light absorber obtained using the light-absorbing composition, and that is likely to contribute to height reduction of an element or a device including the light absorber. The ratio r_{CS} is desirably 2.50 or less, more desirably 2.20 or less.

When a light absorber is produced by curing the light-absorbing composition including the alkoxysilane, a humidification treatment may be performed. In the humidification treatment, the light-absorbing composition is exposed to an atmosphere having a relatively high humidity. It is thought that by the humidification treatment, moisture in the atmosphere promotes hydrolysis of the alkoxysilane in the light-absorbing composition or the light absorber to facilitate formation of a siloxane bond. A hard and dense light absorber can be formed by the humidification treatment without aggregation of particles including the light-absorbing compound.

The alkoxysilane including the group α-1 is not limited to a particular alkoxysilane. Examples of the alkoxysilane including the group α-1 include n-decyltrimethoxysilane, n-undecyltrimethoxysilane, n-dodecyltrimethoxysilane, n-tridecyltrimethoxysilane, n-tetradecyltrimethoxysilane, n-pentadecyltrimethoxysilane, n-hexadecyltrimethoxysilane, n-heptadecyltrimethoxysilane, n-octadecyltrimethoxysilane, n-nonadecyltrimethoxysilane, and n-eicosyltrimethoxysilane. Other examples of the alkoxysilane including the group α-1 include n-decyltriethoxysilane, n-undecyltriethoxysilane, n-dodecyltriethoxysilane, n-tridecyltriethoxysilane, n-tetradecyltriethoxysilane, n-pentadecyltriethoxysilane, n-hexadecyltrimethoxysilane, n-heptadecyltrimethoxysilane, n-octadecyltrimethoxysilane, n-nonadecyltrimethoxysilane, and n-eicosyltrimethoxysilane. Still other examples of the alkoxysilane including the group α-1 include n-decylmethyldiethoxysilane, n-undecylmethyldiethoxysilane, n-dodecylmethyldiethoxysilane, n-tridecylmethyldiethoxysilane, n-tetradecylmethyldiethoxysilane, n-pentadecylmethyldiethoxysilane, n-hexadecylmethyldiethoxysilane, n-heptadecylmethyldiethoxysilane, n-octadecylmethyldiethoxysilane, n-nonadecylmethyldiethoxysilane, and n-eicosylmethyldiethoxysilane. Furthermore, examples of the alkoxysilane including the reactive functional group include 8-glycidoxyoctyltrimethoxysilane and 8-methacryloxyoctyltrimethoxysilane.

The light-absorbing composition may include an alkoxysilane other than the alkoxysilane including the group α-1. The light-absorbing composition may include the silicon-containing compound β being at least one compound selected from the group consisting of the alkoxysilane represented by the formula (2), the hydrolysate of the alkoxysilane, and a polycondensation product of a hydrolysate of the alkoxysilane. The alkoxysilane represented by the formula (2) is not limited to a particular alkoxysilane. Examples of the alkoxysilane represented by the formula (2) include tetramethoxysilane, tetraethoxysilane, tetrapropoxysilane, tetrabutoxysilane, methyltrimethoxysilane, methyltriethoxysilane, propyltrimethoxysilane, propyltriethoxysilane, butyltriethoxysilane, butyltrimethoxysilane, phenyltrimethoxysilane, and phenyltriethoxysilane.

The light-absorbing composition may include a solvent. The solvent is not limited to a particular solvent. The solvent may be an organic solvent. The organic solvent is not limited to a particular organic solvent. The organic solvent may be, for example, an alcohol, a xylene, or a cyclic compound. Examples of the alcohol include methanol, ethanol, n-propanol, i-propanol, n-butanol, i-butanol, 2-butanol, t-butanol, n-pentanol, i-pentanol, 2-methylbutanol, 2-pentanol, t-pentanol, 3-methoxybutanol, n-hexanol, 2-methylpentanol, 1-hexanol, 2-hexanol, 2-ethylbutanol, 1-heptanol, 2-heptanol, 3-heptanol, n-octanol, 2-ethylhexanol, 2-octanol, n-nonylalcohol, 2,6-dimethyl-4-heptanol, n-decanol, cyclohexanol, methylcyclohexanol, 3,3,5-trimethylcyclohexanol, benzyl alcohol, and diacetone alcohol. Examples of the cyclic compound include dichlorobenzene, heptanone, cyclopentanone, cyclohexanone, cyclohexane, dimethylformamide, dimethylacetamide, toluene, tetrahydrofuran (THF), and oxetane.

The light-absorbing composition may include a phosphoric acid ester. A phosphoric acid ester is a compound including a phosphorus atom and an oxygen atom, as does the phosphonic acid; therefore, for example, when the light-absorbing compound includes a phosphoric acid ester and the phosphonic acid, the phosphoric acid ester and the phosphonic acid are expected to have an affinity for each other. The phosphoric acid ester may function as a dispersant for the light-absorbing compound. A portion of the phosphoric acid ester may be present as a compound formed by a reaction with a metal component such as a copper ion. For example, a portion of the phosphoric acid ester may coordinate to the light-absorbing compound, or a portion of the phosphoric acid ester may form a complex with the copper component of the light-absorbing compound. In this case, the compound including the phosphoric acid ester and the copper component can also absorb light with a given wavelength.

The phosphoric acid ester is not limited to a particular phosphoric acid ester. The phosphoric acid ester has, for example, a polyoxyalkyl group. Examples of the phosphoric acid ester include PLYSURF A208N (polyoxyethylene alkyl (C12, C13) ether phosphoric acid ester), PLYSURF A208F (polyoxyethylene alkyl (C8) ether phosphoric acid ester), PLYSURF A208B (polyoxyethylene lauryl ether phosphoric acid ester), PLYSURF A219B (polyoxyethylene lauryl ether phosphoric acid ester), PLYSURF AL (polyoxyethylene styrenated phenylether phosphoric acid ester), PLYSURF A212C (polyoxyethylene tridecyl ether phosphoric acid ester), and PLYSURF A215C (polyoxyethylene tridecyl ether phosphoric acid ester). All of these are products manufactured by DKS Co., Ltd. Examples of the phosphoric acid ester include NIKKOL DDP-2 (polyoxyethylene alkyl ether phosphoric acid ester), NIKKOL DDP-4 (polyoxyethylene alkyl ether phosphoric acid ester), and NIKKOL DDP-6 (polyoxyethylene alkyl ether phosphoric acid ester). All of these are products manufactured by Nikko Chemicals Co., Ltd. One of these phosphoric acid ester compounds may be used alone, or two or more of these phosphoric acid ester compounds may be used in combination.

The light-absorbing composition may be substantially free of the phosphoric acid ester. Since the silicon-containing compound α including the group α-1 is present in the light-absorbing composition, the light-absorbing compound can be favorably dispersed in the light-absorbing composition. For example, in the light-absorbing composition, a ratio of an amount of the phosphoric acid ester to an amount of silicon atoms in the silicon-containing compound α may be 3.0 or less on a molar basis, or the light-absorbing composition may be completely free of the phosphoric acid ester.

As described above, the light-absorbing composition may be free of a curable resin other than the silicon-containing compounds. The light-absorbing composition may include a curable component, such as a curable resin, separately from the silicon-containing compound α and β. Examples of the curable component include a curable resin, a curable polymer, and a monomer, a dimer, and an oligomer that are each a precursor of a curable polymer. The curable component can allow the light-absorbing compound to be dispersed or dissolved and be present in a desired state. When uncured or unreacted, the curable component is liquid. Desirably, the curable component can allow the light-absorbing compound including the phosphonic acid and the copper component to be dispersed or dissolved. Furthermore, a curable resin capable of being applied to a given object to form a coating film by a coating method, such as spin coating, spraying, dipping, or application with a dispenser, is selected as the curable resin. A curable resin capable of being cured into a 1 mm-thick plate-shaped body having a flat and smooth surface is desirably selected as the curable resin, the 1 mm-thick plate-shaped body having a transmission spectrum in which the transmittance in a wavelength range of 450 nm to 800 nm is 90% or more. Examples of the curable resin include a cyclic polyolefin resin, an epoxy-based resin, a polyimide-based resin, a modified acrylic resin, a silicone resin, a polyvinyl-based resin such as PVB, and precursors of these. One of these curable resins may be used alone, or two or more of these curable resins may be used in combination.

The light-absorbing composition may include an ultraviolet absorbent capable of absorbing a portion of light belonging to ultraviolet light. The ultraviolet absorbent is not limited to a particular compound. The ultraviolet absorbent is, for example, a compound not having both a hydroxy group and a carbonyl group in a molecule. For example, curing of the light-absorbing composition can be promoted, for example, by coordination of a reacting substance or a precursor to a particular position in a molecule of the silicon-containing compound α. For example, if there is a group more likely to be coordinated to a substance other than a substance supplied for a reaction for curing the light-absorbing composition, the action of the catalyst may be weakened. In particular, it is conceivable that the silicon-containing compound α is reacted with or coordinated to an ultraviolet absorbent having a hydroxy group and a carbonyl group, both of which are highly electron donative, to partially form a complex. In this case, inherent UV absorption properties of the ultraviolet absorbent may change. In the case where the ultraviolet absorbent is a compound not having both hydroxy group and a carbonyl group in a molecule, the silicon-containing compound α is less likely to form a complex with the ultraviolet absorbent, and the ultraviolet absorbent is likely to exhibit inherent UV absorption properties thereof. The ultraviolet absorbent may include either a hydroxy group or a carbonyl group in one molecule.

The ultraviolet absorbent is selected desirably in view of absorbing light in a desired wavelength range, having compatibility with a particular solvent, dispersing well in the light-absorbing composition, having excellent environmental durability, etc. Examples of the ultraviolet absorbent include a benzophenone-based compound, a benzotriazole-based compound, a salicylic-acid-based compound, and a triazine-based compound. For example, Tinuvin PS, Tinuvin 99-2, Tinuvin 234, Tinuvin 326, Tinuvin 329, Tinuvin 900, Tinuvin 928, Tinuvin 405, and Tinuvin 460 can be used as the ultraviolet absorbent. These are ultraviolet absorbents manufactured by BASF, and Tinuvin is a registered trademark.

The light-absorbing composition may include water, if necessary. The light-absorbing composition includes, for example, a given amount of the alkoxysilanes. For example, the light-absorbing composition can include the silicon-containing compound α as an alkoxysilane. In the light-absorbing composition, the alkoxysilane falling under the category of the silicon-containing compound α or an alkoxysilane not falling under the category of the silicon-containing compound α can be hydrolyzed. The light-absorbing composition may include water because of this hydrolysis. The light-absorbing composition may include an appropriate amount of water depending on the use, function, and storage environment of the light-absorbing composition.

In the process of solidifying the light-absorbing composition to produce a light absorber, a humidification treatment may be carried out as post curing. Through the humidification treatment, a water component at the molecular level can be taken into the light absorber or a precursor thereof so as to facilitate hydrolysis of the alkoxysilane and a subsequent siloxane bond formation reaction. For example, when a process including the humidification treatment is adopted, the light-absorbing composition may be substantially free of water. In this case, the light-absorbing composition may include a water component already coordinated to a compound, such as a hydrate, and a water component not added intentionally but inevitably included.

A method for manufacturing the light-absorbing composition is not limited to a particular method. For example, the light-absorbing composition manufacturing method includes the following steps (I), (II), and (III).
(I) Producing a light-absorbing compound dispersion where a light-absorbing compound including a phosphonic acid and a copper component is dispersed in a solvent.
(II) Mixing the light-absorbing compound dispersion with an alkoxysilane including a group having 10 or more carbon atoms or a hydrolysate of the alkoxysilane.
(III) Removing a portion of the solvent from the light-absorbing compound dispersion.

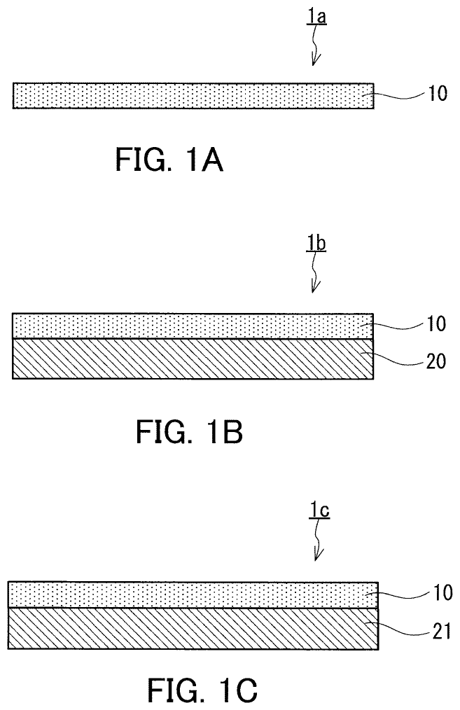

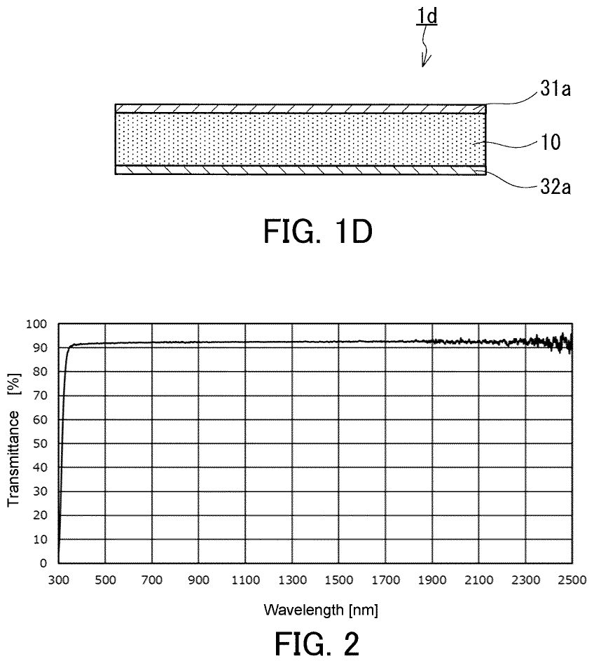

A light absorber 10 as shown in FIG. 1A to FIG. 1D can be provided. The light absorber 10 is provided, for example, as a solidified product of the above light-absorbing composition. In this case, the light absorber 10 includes a polysiloxane including the group α-1 and a siloxane bond. As shown in FIG. 1A, for example, the light absorber 10 can form an optical filter 1a by itself. In this case, the optical filter 1a may have a film shape, or may be a light-absorbing film. As shown in FIG. 1B, an optical filter 1b may be composed of the light absorber 10 and a substrate 20.

The light absorber 10 has an average T^{A}₄₆₀₋₆₀₀ of 80% or more. The average T^{A}₄₆₀₋₆₀₀ is an average transmittance in a wavelength range of 460 nm to 600 nm in a transmission spectrum obtained by allowing light to be incident on the light absorber 10 at an incident angle of 0°. A value determined by dividing an optical density OD of the light absorber 10 at a wavelength λ by a thickness of the light absorber 10 is expressed as η_{λ}[μm⁻¹]. The optical density OD is expressed by OD=−log₁₀[T(λ)/100], where T(λ) is a percentage value of the transmittance at the wavelength λ. In this case, the light absorber 10 satisfies requirements 0.009≤η₃₈₀ and 0.008≤η₇₅₀. Hence, the light absorber 10 is, albeit slim, likely to have transmittances corresponding closely to a human visual sensitivity curve. The light absorber 10 has a high transmittance in the visible region, and can effectively block light with a wavelength not belonging to the visible region by absorption. Moreover, the slim light absorber 10 can be used as an infrared or ultraviolet cut filter. Therefore, an optical filter including the light absorber 10 and disposed near a sensor or a light-receiving face can have a reduced thickness, and the light absorber 10 can contribute to height reduction of imaging apparatuses and light-receiving devices, such as ambient light sensors and illuminance sensors. A transmission spectrum of the light absorber 10 is obtained, for example, by allowing light to be incident on the light absorber 10 at an incident angle of 0° and measuring the transmitted light with a spectrophotometer or the like.

The average T^{A}₄₆₀₋₆₀₀ of the light absorber 10 is desirably 82% or more, more desirably 84% or more. In this case, the light absorber 10 has a higher transmittance in the visible region, and the light absorber 10 is more likely to have transmittances corresponding closely to a human visual sensitivity curve.

The light absorber 10 desirably satisfies a requirement 0.012≤η₃₈₀. The light absorber 10 desirably satisfies a requirement 0.010≤η₇₅₀. In this case, the light absorber 10 can more effectively block light with a wavelength not belonging to the visible region, and the light absorber 10 is more likely to have transmittances corresponding closely to a human visual sensitivity curve.

The light absorber 10 has a haze of, for example, less than 0.2%. For example, an optical filter to be embedded in an imaging apparatus is designed so that transmission and reflection spectra of the optical filter will satisfy a given requirement. Meanwhile, for example, if an optical filter or a light absorber with high haze has a high transmittance in the visible region, a portion of light incident on the optical filter or the light absorber can scatter or be diffused therein and the optical filter or the light absorber can show optical properties, such as cloudiness or opaqueness. That can adversely affect formation of a sharp image. On the other hand, since having a haze less than 0.2%, the light absorber 10 is highly transparent; therefore, for example, an imaging apparatus including the light absorber 10 can obtain a high-quality image. The haze may be measured for the light absorber 10 alone or for the light absorber 10 disposed on a glass or resin substrate.

The light absorber 10 desirably has a haze of 0.18% or less, and more desirably has a haze of 0.15% or less.

The light absorber 10 may satisfy, for example, a requirement 0.018≤η₉₀₀, or a requirement 0.013≤η₁₁₀₀. The light absorber 10 may satisfy a requirement 0.016≤η₈₀₀, or a requirement 0.013≤η₁₀₀₀. In these cases, the light absorber 10 is, albeit slim, more likely to have transmittances corresponding closely to a human visual sensitivity curve.

The light absorber 10 may satisfy desirably a requirement 0.020≤η₉₀₀, a requirement 0.015≤η₁₁₀₀, a requirement 0.018≤η₈₀₀, or a requirement 0.018≤η₁₀₀₀.

The light absorber 10 satisfies, for example, requirements T^{A}₃₀₀₋₃₈₀≤1.5% and T^{A}₇₅₀₋₁₁₀₀≤2.0%. T^{A}₃₀₀₋₃₈₀ is an average transmittance in a wavelength range of 300 nm to 380 nm in a transmission spectrum obtained by allowing light to be incident on the light absorber 10 at an incident angle of 0°. T^{A}₇₅₀₋₁₁₀₀ is an average transmittance in a wavelength range of 750 nm to 1100 nm in the transmission spectrum. In the above case, the light absorber 10 is more likely to have transmittances corresponding closely to a human visual sensitivity curve.

The light absorber 10 desirably satisfies a requirement T^{A}₃₀₀₋₃₈₀≤1.2%, and more desirably satisfies a requirement T^{A}₃₀₀₋₃₈₀≤1.0%. The light absorber 10 desirably satisfies a requirement T^{A}₇₅₀₋₁₁₀₀≤1.5% or less, and more desirably satisfies a requirement T^{A}₇₅₀₋₁₁₀₀≤1.0% or less.

The light absorber 10 may satisfy, for example, a requirement 390 nm≤λ⁰_{UV}≤450 nm and a requirement 600 nm≤λ⁰_{IR}≤680 nm. The symbol λ⁰_{UV} is a first ultraviolet cut-off wavelength that lies in a wavelength range of 350 nm to 460 nm and at which a transmittance is 50%. The symbol AIR is a first infrared cut-off wavelength that lies in a wavelength range of 600 nm to 700 nm and at which a transmittance is 50%. The light absorber 10 desirably satisfies a requirement 393 nm≤λ⁰_{UV}≤450 nm, more desirably a requirement 395 nm≤λ⁰_{UV}≤450 nm. The light absorber 10 desirably satisfies a requirement 605 nm≤λ⁰_{IR}≤680 nm, more desirably a requirement 610 nm≤λ⁰_{IR}≤680 nm.

The light absorber 10 satisfies, for example, a requirement R^{A}₄₅₀₋₅₅₀≤10% and a requirement R^{A}₇₀₀₋₁₀₀₀≤8%. R^{A}₄₅₀₋₅₅₀ is an average reflectance in a wavelength range of 450 nm to 550 nm. R^{A}₇₀₀₋₁₀₀₀ is an average reflectance in a wavelength range of 700 nm to 1000 nm. The reflectance is determined, for example, on the basis of a reflection spectrum obtained by allowing light with wavelengths of 300 nm to 1200 nm to be incident on the light absorber 10 at an incident angle of 5°. When the light absorber 10 capable of absorbing a portion of light with a particular wavelength according to these requirements is, for example, embedded in an imaging apparatus, it is possible to reduce occurrence of reflection or scattering of reflected light inside of a housing of the imaging apparatus or at a diaphragm of the imaging apparatus and ghosting or flare that decreases contrast of an image taken with the imaging apparatus.

The light absorber 10 desirably satisfies a requirement R^{A}₄₅₀₋₅₅₀≤8%. The light absorber 10 desirably satisfies a requirement R^{A}₇₀₀₋₁₀₀₀≤6%.

The light absorber 10 satisfies, for example, a requirement R₃₈₀<R₃₅₀. R₃₈₀ is a reflectance at a wavelength of 380 nm, and R₃₅₀ is a reflectance at a wavelength of 350 nm. In this case, occurrence of ghosting or flare that decreases contrast of an image is more likely to be reduced.

An optical filter including the light absorber 10 may satisfy the above requirements relating to the transmittance, the value na, the haze, and the reflectance.

A thickness di of the light absorber 10 is not limited to a particular value. The thickness di is, for example, 150 μm or less, and is desirably 120 μm or less, more desirably 110 μm or less.

As shown in FIG. 1A, when the light absorber 10 forms the optical filter 1a by itself, the optical filter 1a is likely to be small in thickness and can have a film shape. Consequently, the optical filter 1a is likely to greatly contribute to height reduction of an apparatus in which the optical filter 1a is embedded. Meanwhile, as shown in FIG. 1B, the optical filter 1b including the light absorber 10 and the substrate 20 may be provided. In this case, the optical filter 1b is likely to have high stiffness or mechanical strength, and thus the optical filter 1b can be provided as a rigid optical filter.

A surface of the substrate 20 can be formed, for example, of a glass, a resin, or a metal. The type and optical properties of the substrate 20 are not limited to particular ones as long as the light absorber 10 or an optical filter including the light absorber 10 has a desired transmittance, na, haze, and reflectance. Moreover, the shape of the substrate 20 is not limited to a particular shape. As shown in FIG. 1B, the substrate 20 is, for example, in the shape of a flat plate. In this case, application of the light-absorbing composition is easy, and the optical filter 1b is likely to have great versatility. The substrate 20 may include a curved face or may have a projecting or recessed face. The shape of the substrate 20 may be other than a plate shape. The substrate 20 may be an optical element. Examples of the optical element include a lens, a polarizer, a prism, a reflective element, and a diffraction grating. These optical elements can include a curved face and a flat face. Other examples of the substrate 20 include a photoelectric conversion element, such as a photodiode or a phototransistor, an image sensor in which a lot of photoelectric conversion elements, such as CCDs or CMOSs, are arranged, and an image sensor equivalent to such an image sensor. In some cases, the light absorber 10 may be directly disposed on a light-receiving face or a window glass. Yet another example of the substrate 20 is a display unit, such as a display of a mobile terminal.

The substrate 20 may be transparent. In this case, a transmission spectrum of the optical filter 1b is more reflective of a transmission spectrum of the light absorber 10. For example, when the substrate 20 is transparent, in a transmission spectrum of a 3 mm-thick parallel flat plate made of the same material as that of the transparent substrate 20, the transmittance in a wavelength range of 360 nm to 900 nm is 90% or more, and the transmittance in a wavelength range of 350 nm to 1200 nm can be 85% or more. The material of the substrate 20 having such transmission properties is typically glass. The substrate 20 may be a transparent glass substrate including a silicate glass.

Examples of the silicate glass include soda-lime glass and borosilicate glass. The borosilicate glass is, for example, D263 T eco manufactured by SCHOTT AG. FIG. 2 shows a transmission spectrum of a 3 mm-thick flat plate of D263T eco. In this transmission spectrum, the transmittance in a wavelength range of 360 nm to 2300 nm is 90% or more, and the transmittance in a wavelength range of 335 nm to 2500 nm is 85% or more. The glass included in the substrate 20 may be a phosphate or fluorophosphate glass containing a coloring component, such as Cu or Co. The glass containing a coloring component is, for example, infrared-absorbing glass. In this case, the substrate 20 has light absorption properties in itself. When the substrate 20 is a substrate including an infrared-absorbing glass, desired optical properties are likely to be imparted to the optical filter 1b by adjusting the light absorption properties and the transmission spectra of both the light absorber 10 and the substrate 20. Moreover, the flexibility in designing the optical filter 1b is likely to increase.

The substrate 20 may include a resin. Examples of the resin included in the substrate 20 include a cycloolefin resin such as a norbornene resin, a polyarylate resin, an acrylic resin, a modified acrylic resin, a polyimide resin, a polyetherimide resin, a polyolefin resin, a polysulfone resin, a polyethersulfone resin, a polycarbonate resin, and a silicone resin. Resins are easily processable and shapable, compared to glasses. Therefore, when the substrate 20 includes the resin, the substrates 20 in various shapes, such as optical elements, can be obtained.

As shown in FIG. 1C, an optical filter 1c includes the light absorber 10 and a light-absorbing-type substrate 21. The light-absorbing-type substrate 21 is a substrate having a function of absorbing a portion of light with a particular wavelength, the substrate having a surface on which the light absorber 10 can be disposed. The light-absorbing-type substrate 21 may include any of the above glasses including a coloring component, or may be a resin substrate including a dye, a pigment, or a coloring.

An optical filter including the light absorber 10 may include an anti light reflection film or a light reflection reduction film for prevention or reduction of surface reflection of light incident on the optical filter. In this case, the anti light reflection film or the light reflection reduction film (hereinafter collectively referred to as “antireflection film”) forms a surface of the optical filter. As shown in FIG. 1D, an optical filter 1d includes the light absorber 10 and antireflection films 31a and 31b provided on surfaces of the light absorber 10. The antireflection films 31a and 31b are disposed along the surfaces of the light absorber 10. For example, when an optical filter includes a transparent substrate and the light absorber 10 disposed on the transparent substrate, an antireflection film may be disposed on each of the surface of the light absorber 10 not in contact with the transparent substrate and the surface of the transparent substrate not in contact with the light absorber 10. Such a light absorber provided with an antireflection film and such an optical filter including a light absorber and an antireflection film are also included in the gist of the present invention.

The antireflection film can increase, for example, the transmittance of the light absorber 10 or an optical filter including the light absorber 10 in a wavelength band, the light absorber 10 or the optical filter being configured to transmit light in the wavelength band (transmission wavelength band). The transmission wavelength band is, for example, a wavelength band in which the transmittance is 50% or more in a transmission spectrum of the light absorber or the optical filter at an incident angle of 0°.

When the antireflection film is formed on the light absorber 10, an optical filter, or a transparent substrate (e.g., D263 T eco manufactured by SCHOTT AG) for supporting them, the reflectance in a wavelength range of 400 nm to 600 nm is, for example, 1% or less in a reflection spectrum obtained by allowing light with wavelengths from 300 nm to 1200 nm to be incident at an incident angle of 5°. This reflectance is desirably 0.5% or less, more desirably 0.25% or less.

In this reflection spectrum, the average reflectance in a wavelength range of 700 nm to 1200 nm is, for example, 1% or less. In this case, a portion of light belonging to infrared light is less likely to be reflected to cause ghosting or flare in obtained images. This average reflectance is desirably 0.5% or less, and more desirably 0.25% or less.

When the antireflection film is formed on the light absorber 10 or the like, the reflectance in the wavelength range of 400 nm to 600 nm is, for example, 3% or less in a reflection spectrum obtained by allowing light with wavelengths from 300 nm to 1200 nm to be incident at an incident angle of 50°. In this case, even when light is incident on the light absorber 10 or an optical filter including the light absorber 10 at a large incident angle, the light absorber 10 or the optical filter including the light absorber 10 has a low reflectance. The reflectance is desirably 1% or less. In this reflection spectrum, the reflectance in the wavelength range of 700 nm to 1200 nm is, for example, 3% or less. In this case, even when light is incident on the light absorber 10 or an optical filter including the light absorber 10 at a large incident angle, the light absorber 10 or the optical filter including the light absorber 10 has a low reflectance. The reflectance is desirably 1.5% or less.

The antireflection film is not limited to a particular film. The antireflection film includes at least one layer selected from the group consisting of the following layers (a), (b), and (c). The antireflection film may include two or more layers selected from this group. In the example shown in FIG. 1D, the antireflection films 31a and 32a are each composed of one layer; actually, each antireflection film is shown functionally in this figure so as to be differentiated from the light absorber 10. Practically, the antireflection films 31a and 32a may each be a single-layer film composed of a single layer and be formed of approximately the same materials, or the antireflection films 31a and 32a may each be a multilayer film composed of layers formed of different materials from each other.
(a) A layer formed by a sol-gel process using a reactive material including silicon
(b) A layer formed by a sol-gel process using a reactive material including silicon, the layer further including fine particles
(c) A layer formed by a physical film formation method such as vacuum deposition or sputtering

Regarding the above layer (a), the reactive material including silicon is not limited to a particular material. The reactive material desirably includes a trifunctional silane such as methyltriethoxysilane (MTES) and a tetrafunctional silane such as tetraethoxysilane (TEOS). The tetrafunctional silane is important to form a layer having a firm and dense structure. However, using the tetrafunctional silane alone makes it difficult to control the reactivity and narrows the range of choices about porosity. Additionally, cracking easily occurs. Addition of the trifunctional silane improves the flexibility of the silica structure, increases the controllability of the porosity, and reduces occurrence of cracking. Hence, refractive index adjustment which is necessary for the antireflection film can be accomplished by adjusting the porosity. An organic functional group included in the trifunctional silane is not limited to a particular functional group. The organic functional group is, for example, a methyl group. In this case, a uniform solution and a uniform coating film can be easily formed by including a combination of the trifunctional silane and the tetrafunctional silane. A ratio of an amount of the trifunctional silane to an amount of the tetrafunctional silane is not limited to a particular value. The ratio is, for example, ⅓ to 5 on a molar basis. In this case, occurrence of cracking in the antireflection film is reduced by the tetrafunctional silane while a firmer structure can be formed with the trifunctional silane. The reactive material including silicon may further include a bifunctional silane.

The trifunctional silane is not limited to a particular silane. Examples of the trifunctional silane include methyltriethoxysilane, methyltrimethoxysilane, ethyltriethoxysilane, ethyltrimethoxysilane, propyltriethoxysilane, propyltrimethoxysilane, butyltriethoxysilane, butyltrimethoxysilane, pentyltrimethoxysilane, pentyltriethoxysilane, hexyltriethoxysilane, and hexyltrimethoxysilane. The trifunctional silane may be a trifunctional silane having an alkyl group directly bonded to a silicon atom (Si). The tetrafunctional silane is not limited to a particular silane. Examples of the tetrafunctional silane include tetraethoxysilane, tetramethoxysilane, tetrapropoxysilane, and tetrabutoxysilane.

A silane compound included in the reactive material including silicon also turns into a hydrolysate of a silane compound including a silanol group by hydrolysis. Then, by polycondensation of the hydrolysate, the trifunctional silane can turn into (poly)silsesquioxane, and the tetrafunctional silane can be changed to have a structure of silica.

Since refractive indices of (poly)silsesquioxane and silica are as low as around 1.46, a layer having a low refractive index is likely to be formed. A layer including at least one selected from the group consisting of (poly)silsesquioxane and silica is suitable as a layer included in the antireflection film of the light absorber 10 or an optical filter including the light absorber 10.

The coating film of the reactive material can be fired, for example, in a temperature range of 60° C. to 170° C. The firing is performed desirably in a temperature range of 60° C. to 150° C., and more desirably in a temperature range of 60° C. to 115° C.

Regarding the above layer (b), the layer including the above reactive material including silicon, a hydrolysate of the above reactive material, or a polycondensation product of the hydrolysate includes particles. The particle includes, for example, at least one selected from the group consisting of silica, titania, zirconia, alumina, and magnesium fluoride. The material of the particle has a refractive index of, for example, 1.30 to 2.55. The particle desirably includes silica. In the layer including silica or (poly)silsesquioxane, the silica or the (poly)silsesquioxane functions as a binder surrounding the particle. Consequently, a bonding strength acting between the particle and the binder via the silanol group or the like increases, the weather resistance of the antireflection film is likely to increase, and enhancement of the reliability of the antireflection film can be expected.

The particles included in the layer (b) may be hollow particles. A layer including the hollow particles, silsesquioxane, and silica is defined as a layer (b1) to differentiate the layer from a later-described layer including solid particles. Since the hollow particle has an empty space inside, the refractive index thereof tends to be very low. The hollow particle has a refractive index of, for example, 1.02 to 1.50. An average particle diameter of the hollow particles is, for example, 5 nm to 200 nm. The average particle diameter of the fine particles is, for example, a particle diameter (median diameter) at 50% in a number-based cumulative undersize distribution curve measured using a laser diffraction-scattering particle size analyzer by laser diffraction-scattering. For example, a laser diffraction-scattering particle diameter distribution measurement device “LA-960V2 series” manufactured by HORIBA, Ltd. or the like can be used as the laser diffraction-scattering particle size analyzer. Alternatively, the average particle diameter of the fine particles may be determined by observing a cross-section of a structural body including the layer (b1) with a scanning electron microscope (SEM) at 100,000-fold magnification, measuring particle diameters of fine particles in the microscopic field or a given range (e.g., 500 nm²), and determining the average of the particle diameters. This method may be used to determine diameters of fine particles, particularly, included in a solidified or solid layer. A content of the fine particles in the layer (b1) is, for example, 5 mass % to 95 mass %. The content of the fine particles in the layer (b1) is, for example, 30 volume % to 99 volume %. The content of the fine particles in the layer (b1) is determined by observing a cross-section of a structural body including the layer (b1) with a SEM at 100,000-fold magnification in the same manner and calculating a ratio of a volume of the fine particles to a volume of the layer (b1). Commonly, the larger the ratio of the fine hollow particles in the layer (b1) is, the lower refractive index the layer tends to have. The content of the fine particles in the layer (b1) may be, for example, 75 volume % to 99 volume %.

A layer including hollow particles as described above and at least one selected from the group consisting of silica and (poly)silsesquioxane is likely to have a very low refractive index. For example, the refractive index of the layer (b1) is, for example, 1.00 to 1.45. The hollow particle may be a hollow silica particle. For example, THRULYA 4110 or 1110 manufactured by JGC Catalyst and Chemicals Ltd. can be used. The refractive index of the layer (b1) may be determined as follows. A layered body including a substrate having known refractive indices in a particular wavelength range and the layer (b1) provided on a surface of the substrate is produced, and is measured for a reflection spectrum. Then, a thickness of the layer (b1) is determined from an enlarged SEM image of a cross-section or by measurement with a laser length-measuring microscope or the like. By setting the refractive index of the layer (b1) as a variable, a refractive index being most fitting with the measured reflection spectrum is calculated.

The layer including at least one selected from the group consisting of silica and (poly)silsesquioxane and the hollow particles tends to have a low refractive index, compared with the layer including at least one selected from the group consisting of silica and (poly)silsesquioxane and not including the hollow particles. Therefore, the antireflection film can have a high reflection prevention effect in a structure in which the layer including at least one selected from the group consisting of silica and (poly)silsesquioxane and the hollow particles, the layer including at least one selected from the group consisting of silica and (poly)silsesquioxane and not including the hollow particles, and an optical filter or the light absorber 10 are stacked in this order.

The fine particles included in the layer (b) may be solid particles. A layer including the solid particles, silsesquioxane, and silica is defined as a layer (b2) to differentiate the layer from the above-described layer including the hollow particles. The solid particle has a refractive index of, for example, 1.25 to 2.75. When the layer (b) includes the solid particles, the layer (b2) has a refractive index of, for example, 1.40 to 2.50. An average particle diameter of the solid particles may be, for example, 2 nm to 200 nm. The solid particle may be a solid silica particle. For example, SNOWTEX MP-2040manufactured by Nissan Chemical Industries, Ltd. can be used. The refractive index of the layer (b2) may be determined by the same method as that for the layer (b1).

The layer (b2) may include particles having a relatively high refractive index. The layer (b2) may be formed as a layer having a relatively high refractive index. For example, the layer (b2) may include one selected from the group consisting of TiO₂ (titanium oxide; refractive index: 2.33 to 2.55), Ta₂O₅ (tantalum oxide; refractive index: 2.16), Nb₂O₅ (niobium oxide; refractive index: 2.33), and Si₃N₄ (silicon nitride; refractive index: 2.02), or may include a mixture of at least two selected from this group. In particular, the layer (b2) may include TiO₂ particles. In this case, an average particle diameter of the TiO₂ particles may be 2 nm to 200 nm. A content of the TiO₂ particles in the layer (b2) is, for example, 2% to 50%. For example, NS405 manufactured by Tayca Corporation, TTO-51A manufactured by ISHIHARA SANGYO KAISHA, LTD., or the like can be used as the TiO₂ particles. An average particle diameter of the fine particles included in the layer (b2) may be determined by the same method as that for the average particle diameter of the fine particles included in the layer (b1). A content of the fine particles included in the layer (b2) is, for example, 5 mass % to 95 mass %. The content of the fine particles included in the layer (b2) is, for example, 30 volume % to 99 volume %. The content of the fine particles included in the layer (b2) may be determined by the same method as that for the percentage by volume of the fine particles included in the layer (b1).

These particles may be surface-treated with a silane coupling agent, a titanium coupling agent, or the like to improve adhesiveness or wettability between the particle and the binder or a matrix. This surface treatment may be effective for particles other than TiO₂ particles and SiO₂ particles.

The layers (a), (b1), and (b2) each include the silicon compound as a binder or a matrix, as does the light absorber including the silicon compound. Because of this, it is conceivable that an alkoxy group or a hydrolysate thereof, namely a silanol group, is present between the layers and reacts with a hydroxy group or the like, thereby improving the adhesiveness and contributing to improvement of peel resistance or the like. The layers (a), (b1), and (b2) are classified, for example, as a low-refractive-index layer, a middle-refractive-index layer, and a high-refractive-index layer. In this case, the low-refractive-index layer is the layer (b1) including at least one selected from the group consisting of silica and (poly)silsesquioxane and the hollow particles. The middle-refractive-index layer is the layer (a) including at least one selected from the group consisting of silica and (poly)silsesquioxane and not including the hollow particles. The high-refractive-index layer is the layer (b2) including at least one selected from the group consisting of silica and (poly)silsesquioxane and the particles, such as TiO₂ particles, having a relatively high refractive index. For example, the antireflection film may be configured taking account of, for example, a combination of these layers, the thicknesses of the layers, the numbers of layers, and a repetitive pattern of the combination of the layers. According to comparison between the layers, the refractive indices of the layers satisfy the following requirement: the refractive index of the layer (b1)<the refractive index of the layer (a)<the refractive index of the layer (b2).

The antireflection film may be configured such that the layer (b1) including silica, (poly)silsesquioxane, and the hollow particles and the layer (b2) including silica, (poly)silsesquioxane, and the solid particles, such as TiO₂ particles, having a relatively high refractive index are stacked. The refractive index of the layer (b2) is higher than that of the layer (b1). Stacking layers having substantially different refractive indices to form the antireflection film, as just described, is very effective, for example, in expanding an antireflection band and reducing the reflectance.

The layers (a), (b1), and (b2) can be produced by a known method. Specifically, the trifunctional alkoxysilane being the material of a silsesquioxane, the tetrafunctional silane being the material of silica, an acidic or alkaline catalyst, and water for hydrolysis are mixed and hydrolyzed in an organic solvent where an alkoxysilane and water are soluble to give a sol-type precursor of a layer such as the layer (a), (b1), or (b2). Especially for a precursor of a layer such as the layer (b1) or (b2), the hollow particles or the solid particles are added, as necessary. The hollow particles or the solid particles may be subjected to a silane treatment in advance with a silane coupling agent or the like. In that case, adhesiveness and wettability with the binder (a compound including silsesquioxane and silica and capable of being bonded to the particles) can be improved.

The thus-prepared sol-type precursor is applied to a substrate, which is a surface of a light absorber or an optical filter in this case, that needs an antireflection effect. Application conditions and an application amount were adjusted so that the sol-type precursor will have a given thickness. Examples of the application method include spin coating, dip coating, roll coating, dispensing, spray coating, and bar coating, and the application method may be other than these. After the application of the sol-type precursor, reactions such as hydrolysis of the alkoxysilane and polycondensation of a hydrolysate thereof progress to solidify the sol-type precursor. Desirably, heating may be carried out on the purpose of promoting the reactions or removing a by-product. Except for the reactions in the sol, a solidification process where a gel is produced by evaporation or drying of the solvent or a liquid component may be included.

The above layer (c) can be formed as a layer formed of a dielectric or a metal oxide by physical deposition such as vacuum deposition including ion assist deposition (IAD), sputtering, or ion plating. The material of the layer (c) is not limited to a particular material. The layer (c) includes, for example, at least one material selected from the group consisting of SiO₂, TiO₂, Ta₂O₃, SnO₂, In₂O₃, Nb₂O₅, Si₃N₄, TiNₓ, and MgF₂. The layer (c) may be formed of a material given by mixing two or more of these compounds in a given proportion, and a refractive index of a layer included in the layer (c) may be adjusted by adjusting the mixing proportion in the material given by mixing the different compounds.

The layer (c) may be a single layer made of one single material only, or, for example, may be a multilayer in which two or more layers including different materials selected from the above compounds and their mixtures are stacked. When the layer (c) is a multilayer, the antireflection film may be formed, for example, by adjusting thicknesses of layers and the number of layers and alternatively stacking the layers. The layers are, for example, a layer made of a relatively-high-refractive-index material such as TiO₂, Ta₂O₃, or Nb₂O₅ or a mixture thereof and a layer made of a relatively-low-refractive-index material such as SiO₂ or MgF₂ or a mixture thereof. In this case as well, stacking the layers having substantially different refractive indices to form the antireflection film is expected to be very effective, for example, in expanding an antireflection band and reducing the reflectance, and is favorable to the users of an optical filter or a light absorber.

For the optical filter 1d in which the antireflection films 31a and 32a are provided on the two surfaces of the light absorber 10, an average transmittance T₂^{A}₄₆₀₋₆₀₀ in the wavelength range of 400 nm to 600 nm is desirably 90% or more, more desirably 94% or more. In this case, the optical filter 1d transmits light with a wavelength in the visible region with little attenuation. This means that the optical filter 1d has extremely favorable properties as an optical filter to be included in imaging apparatuses.

Moreover, for the optical filter 1d in which the antireflection films 31a and 32a are provided on the two surfaces of the light absorber 10, when a value determined by dividing an optical density OD at a wavelength λ by the thickness of the light absorber (the thickness determined by subtracting the thickness of the antireflection film from that of the optical filter) is expressed as η_{2-λ}[μm⁻¹], 0.009≤η₂₋₃₈₀ and 0.008≤η₂₋₇₅₀ are desirably established, and 0.012≤η₂₋₃₈₀ and 0.010≤η₂₋₇₅₀ are more desirably established.

The optical filter 1d in which the antireflection films 31a and 32a are provided on the two surfaces of the light absorber 10 desirably has a haze less than 0.2%, more desirably a haze of 0.18% or less, particularly desirably a haze of 0.15% or less, as does an optical filter including no antireflection film.

The optical filter 1d in which the antireflection films 31a and 32a are provided on the two surfaces of the light absorber 10 may satisfy, for example, a requirement 0.020≤η₂₋₉₀₀, or may satisfy a requirement 0.013≤η₂₋₁₁₀₀. The optical filter 1d may satisfy a requirement 0.020≤η₂₋₈₀₀, or may satisfy 0.012≤η₂₋₁₀₀₀.

The optical filter 1d desirably may satisfy a requirement 0.022≤η₂₋₉₀₀, or may satisfy a requirement 0.015≤η₂₋₁₁₀₀, a requirement 0.025≤η₂₋₈₀₀, or a requirement 0.015≤η₁₂₋₁₀₀₀.

The optical filter 1d in which the antireflection films 31a and 32a are provided on the two surfaces of the light absorber 10 may satisfy, for example, requirements T₂^{A}₃₀₀₋₃₈₀≤1.5% and T₂^{A}₇₅₀₋₁₁₀₀≤2.0%, desirably requirements T₂^{A}₃₀₀₋₃₈₀≤1.2% and T₂^{A}₇₅₀₋₁₁₀₀≤1.5%, even more desirably requirements T₂^{A}₃₀₀₋₃₈₀≤1.0% and T₂^{A}₇₅₀₋₁₁₀₀≤1.0%. T₂^{A}₃₀₀₋₃₈₀ is an average transmittance in a wavelength range of 300 nm to 380 nm, and T₂^{A}₇₅₀₋₁₁₀₀ is an average transmittance in a wavelength range of 750 nm to 1100 nm.

The optical filter 1d in which the antireflection films 31a and 32a are provided on the two surfaces of the light absorber 10 satisfies, for example, requirements 390 nm≤λ₂⁰_{UV}≤450 nm and 600 nm≤λ₂⁰_{IR}≤680 nm. For the optical filter 1d, λ₂⁰_{UV} is a second ultraviolet cut-off wavelength that lies in the wavelength range of 350 nm to 460 nm and at which a transmittance is 50%, and λ₂⁰_{IR} is a second infrared cut-off wavelength that lies in the wavelength range of 600 nm to 700 nm and at which a transmittance is 50%.

An ambient light sensor including the light absorber 10 or an optical filter including the light absorber 10 may be provided. An ambient light sensor is a device configured to be mounted in an apparatus for detection of the brightness, the hue, or the like around the apparatus. An ambient light sensor included in an apparatus recognizes an attribute of light around the apparatus and, for example, automatically adjusts the brightness or the like of a display device, such as a display, mounted in the apparatus. Ambient light sensors are sometimes called luminance sensors or illuminance sensors.

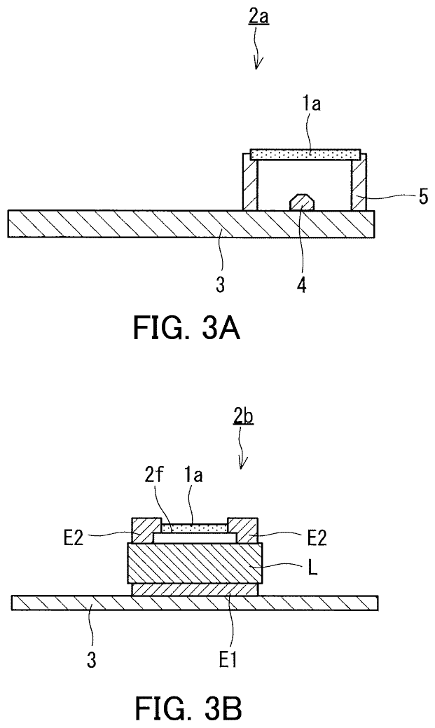

FIG. 3A is a cross-sectional view showing an example of an ambient light sensor. As shown in FIG. 3A, an ambient light sensor 2a includes, for example, an electric circuit board 3, a photoelectric conversion element 4, a housing 5, and the optical filter 1a. The ambient light sensor 2a detects, for example, an attribute of light belonging to the visible region among attributes of light around an apparatus including the ambient light sensor 2a. The electric circuit board 3 supports the ambient light sensor 2a, and electrically connects the ambient light sensor 2a to a nearby device. The photoelectric conversion element 4 is disposed on the electric circuit board 3 and includes, for example, an element such as a photodiode or a phototransistor. The housing 5 is disposed on the electric circuit board 3 and surrounds the photoelectric conversion element 4. The optical filter 1a is disposed, for example, in front of the photoelectric conversion element 4 so as to block a portion of light traveling toward the photoelectric conversion element 4. The optical filter 1a blocks, for example, a portion of light belonging to ultraviolet light or infrared light. The optical filter 1a is supported by the housing 5.

An ambient light sensor may include, as shown in FIG. 3A, an optical filter including the light absorber 10, or may include, for example, as shown in FIG. 3B, an integrated photoelectric conversion element in which the light absorber 10 and a photoelectric conversion element are integrated. A photoelectric conversion element 2b shown in FIG. 3B includes a light-receiving face 2f and the light absorber 10. In the photoelectric conversion element 2b, the light-receiving face 2f and the light absorber 10 are disposed in this order. The photoelectric conversion element 2b is an integrated photoelectric conversion element. The integrated photoelectric conversion element is obtained, for example, by applying the above light-absorbing composition to a surface of the light-receiving face (a pane) of the photoelectric conversion element and curing the applied light-absorbing composition to form the light absorber 10. Such a photoelectric conversion element eliminates the need for a light absorber separated from the photoelectric conversion element. The ambient light sensor as described above can block, for example, light outside the visible region, such as a portion of light belonging to ultraviolet light or infrared light by absorption by means of the light absorber 10. That can significantly enhance the usability of the ambient light sensor as an ambient light sensor specialized in detection of light in an approximate visible region. Moreover, simplification of a supply chain for distribution of product can be expected.

In the photoelectric conversion element 2b, for example, a first electrode E1 and a photoelectric conversion layer L are stacked in this order on the electric circuit board 3. Additionally, a second electrode E2, the light-receiving face 2f, and the light absorber 10 are disposed on the photoelectric conversion layer L.

In order to reduce the reflectance and increase the transmittance of light with a given wavelength, the antireflection film or a reflection reduction film may be provided on a surface of the light absorber 10 to be mounted in an ambient light sensor or an optical filter to be mounted in an ambient light sensor, the optical filter including the light absorber 10.

An imaging apparatus or a camera module including the light absorber 10 or an optical filter including the light absorber 10 can be provided. An imaging apparatus or a camera module includes, for example, an image sensor, an electric circuit board, a lens system, and an optical filter including the light absorber 10. In the image sensor, for example, a lot of photoelectric conversion elements, such as CCDs or CMOSs, are arranged. The electric circuit board electrically connects the image sensor to an external device. The lens system includes one lens group or two or more lens groups for condensing light from a subject or the like on the image sensor and forming an image. The light absorber 10 or an optical filter including the light absorber 10 can block a portion of light belonging to ultraviolet light and infrared light.

For example, in the imaging apparatus in which the light absorber 10 or an optical filter including the light absorber 10 is mounted, a portion of light belonging to ultraviolet light and infrared light is blocked by absorption and light belonging to the visible region passes through the optical filter toward the image sensor. In the case where an optical filter has a function of reflecting a portion of light by means of a dielectric multilayer film or the like, a portion of light reflected by the optical filter is reflected on a surface of a lens system disposed in front of the optical filter inside a housing to reach a light-receiving face of an imaging device, or a portion of such reflected light projects a shadow of a diaphragm or the shape of the diaphragm on the light-receiving face of the imaging device. Consequently, a phenomenon, such as ghosting or flare, that spoils contrast comes to the fore. On the other hand, the imaging apparatus in which an optical filter including the light absorber 10 is mounted reduces occurrence of such a phenomenon and ghosting, flare, or the like is less conspicuous in an image obtained with the imaging apparatus.

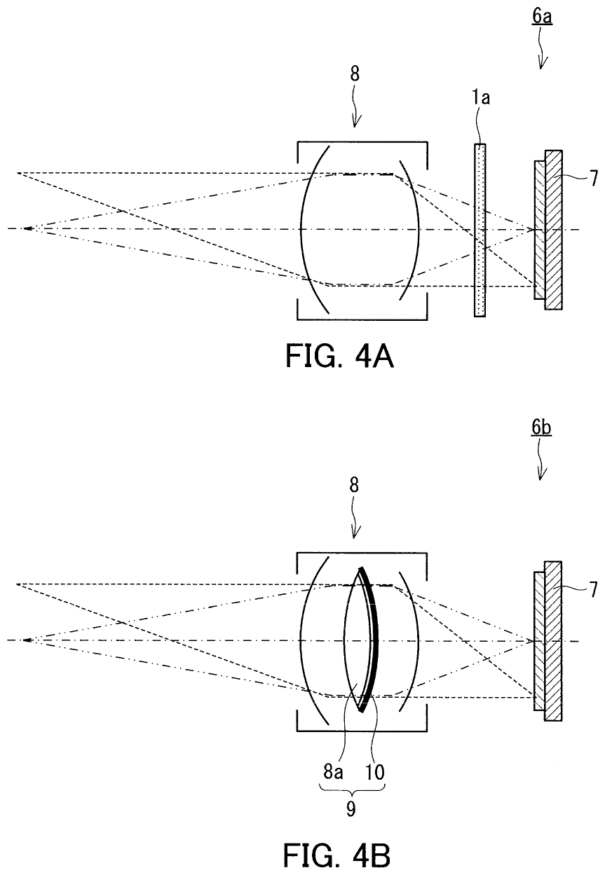

FIG. 4A shows an example of the imaging apparatus. This figure schematically shows the imaging apparatus. Only the elements necessary for description are schematically described, and other parts and elements are omitted. As shown in FIG. 4A, an imaging apparatus 6a includes an image sensor 7, a lens system 8, and the optical filter 1a. In the imaging apparatus 6a, the optical filter 1a is disposed, for example, between the image sensor 7 and the lens system 8 and just in front of the image sensor 7. The position of the optical filter is not limited to the position shown in FIG. 4A. The optical filter may be disposed on the subject side, i.e., in front of the lens system 8. In this case, the optical filter includes, for example, the light absorber 10 and a transparent dielectric substrate supporting the light absorber 10. When a rigid substrate, such as a glass substrate, is used as the transparent dielectric substrate, the optical filter can be expected to have a function as a protecting filter for protecting the imaging apparatus and the lens system from the outside.

FIG. 4B shows another example of the imaging apparatus. An imaging apparatus 6b is configured in the same manner as the imaging apparatus 6a, unless otherwise described. As shown in FIG. 4B, in the imaging apparatus 6b, the light absorber 10 is disposed on a surface of a lens 8a being part of the lens system 8. For example, by applying the above light-absorbing composition to the surface of the lens 8a and curing the applied light-absorbing composition, the light absorber 10 can be disposed such that an interface is formed between the light absorber 10 and the lens 8a. In this case, without a light-absorbing optical filter provided separately from the lens system 8, the lens system 8 can have desired light blocking properties, and therefore significant simplification of assembling or manufacturing of the imaging apparatus can be expected.

The above-described lens 8a formed integrally with the light absorber 10 or a lens system including the above-described lens 8a may be distributed. The antireflection film or a reflection reduction film may be formed on a surface of the light absorber 10. In that case, reflected light from the surface of the light absorber 10 is likely to be reduced, and transmitted light in the visible region is likely to increase. In the imaging apparatus 6b, the position of the light absorber 10 is not limited to the position thereof shown in FIG. 4B.

Some lens systems of imaging apparatuses include a group of lenses, the group being formed of two or more lenses whose surfaces are bonded to each other. An adhesive or a curable resin can be used to bond the lenses. Though not illustrated, the above light-absorbing composition may be used as such an adhesive or the like for bonding the lenses. In that case, the light absorber 10 is less likely to be affected by an external environment of the lens system, and protection of the light absorber 10 or the components included in the light absorber 10 are expected. If the light-absorbing composition is prepared so that the refractive indices of the light absorber 10 and the lens forming an interface with the light absorber 10 will be approximately the same, there is an advantage in that reflection at the interface between the light absorber 10 and the lens can be reduced so significantly that no antireflection coating is necessary.

### EXAMPLES

The present invention will be described in more detail by examples. The present invention is not limited to the examples given below.

### Example 1

An amount of 4.500 g of copper acetate monohydrate and 240 g of tetrahydrofuran (THF) were mixed, and the mixture was stirred for three hours to obtain a solution (1-A) being a copper acetate solution. An amount of 40 g of THF was added to 0.610 g of phenylphosphonic acid, and the mixture was stirred for 30 minutes to obtain a solution (1-B). An amount of 40 g of THF was added to 3.660 g of 4-bromophenylphosphonic acid, and the mixture was stirred for 30 minutes to obtain a solution (1-C). An amount of 40 g of THF was added to 0.758 g of n-butylphosphonic acid, and the mixture was stirred for 30 minutes to obtain a solution (1-D). The solution (1-A) was mixed with the solutions (1-B), (1-C), and (1-D). An amount of 4.00 g of n-hexadecyltrimethoxysilane being a trifunctional alkoxysilane and 2.78 g of tetraethoxysilane being a tetrafunctional alkoxysilane were added to the mixture, which was further stirred for one minute to obtain a solution (1-E). To the solution (1-E) was then added 40 g of toluene, and the mixture was stirred at room temperature for one minute to obtain a solution (1-F). The solution (1-F) was put in a flask and subjected to a treatment using a rotary evaporator (manufactured by Tokyo Rikakikai Co., Ltd.; product code: N-1110SF) under heating by means of an oil bath (manufactured by Tokyo Rikakikai Co., Ltd.; product code: OSB-2100) to carry out a reaction and remove THF. The temperature of the oil bath was controlled to 85° C. The solution having undergone the treatment was collected from the flask. A light-absorbing composition (1-G) being a liquid light-absorbing composition according to Example 1 and including a light-absorbing compound including a phosphonic acid and a copper component and a silicon-containing compound including a n-hexadecyl group was obtained in this manner. Table 1 shows addition amounts (contents) of the compounds for preparation of the light-absorbing composition according to Example 1. Table 1 also shows addition amounts (contents) of the compounds for preparation of light-absorbing compositions according to other Examples and Comparative Examples.

A coating film of the light-absorbing composition (1-G) was formed on one principal surface of a borosilicate glass substrate (manufactured by SCHOTT AG; product name: D263 T eco) having dimensions of 76 mm×76 mm×0.21 mm with a dispenser. After the coating film was sufficiently dried at room temperature, the substrate and the coating film were put in an oven and heated for approximately six hours from room temperature to 85° C. to sufficiently carry out a reaction of the alkoxysilanes and evaporate the organic solvent in the light-absorbing composition (1-G). After that, the coating film was left to stand still in an environment at a temperature of 85° C. and a relative humidity of 85% for another eight hours for post curing, and the reaction was completed. The light absorber according to Example 1 was obtained in this manner. An optical filter according to Example 1 in which the light absorber according to Example 1 was disposed on the substrate was also obtained.

The haze of the light absorber according to Example 1 was measured according to Japanese Industrial Standards (JIS) K 7136:2000 using a haze meter HM-65L2 manufactured by MURAKAMI COLOR RESEARCH LABORATORY. As shown in Table 2, the haze value of the light absorber according to Example 1 was 0.19%. Table 2 shows haze values of the light absorbers according to other Examples and Comparative Examples except for those not measured.

The light absorber according to Example 1 was measured for its thickness using a laser displacement meter LK-H008 manufactured by Keyence Corporation. As shown in Table 2, the light absorber according to Example 1 had a thickness of 97 μm. Table 2 shows thicknesses of the light absorbers according to other Examples and Comparative Examples except for those not measured.

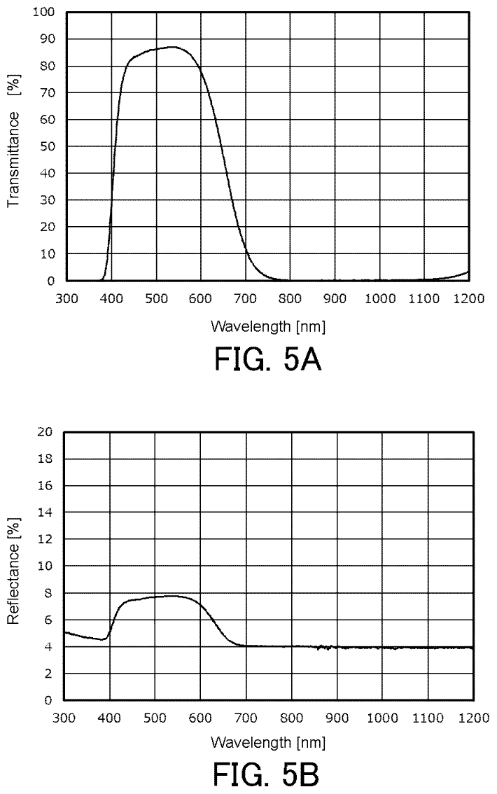

A transmission spectrum was measured for the light absorber according to Example 1 at an incident angle of 0° using an ultraviolet-visible-near-infrared spectrophotometer V-770 manufactured by JASCO Corporation and equipped with a transmitted light measurement attachment. For the transmittance spectrum measurement, an environment around the optical filter was adjusted at a temperature of 22 to 25° C., unless otherwise specified. The measurement attachment used in this measurement was replaced with a reflected light measurement attachment, with which a reflection spectrum of the light absorber according to Example 1 at an incident angle of 5° was measured. For the reflection spectrum measurement, an environment around the optical filter was adjusted at a temperature of 22 to 25° C., unless otherwise specified. FIG. 5A shows the transmission spectrum of the light absorber according to Example 1. FIG. 5B shows the reflection spectrum of the light absorber according to Example 1. Table 2 shows property values relating to optical requirements for the light absorber at an incident angle of 0°. Table 3 shows values na each determined by dividing an optical density at a particular wavelength by the thickness of the light absorber. Tables 2 and 3 show property values relating to transmittances and reflectances and values na of the light absorbers according to other Examples and Comparative Examples.

### Examples 2 to 14

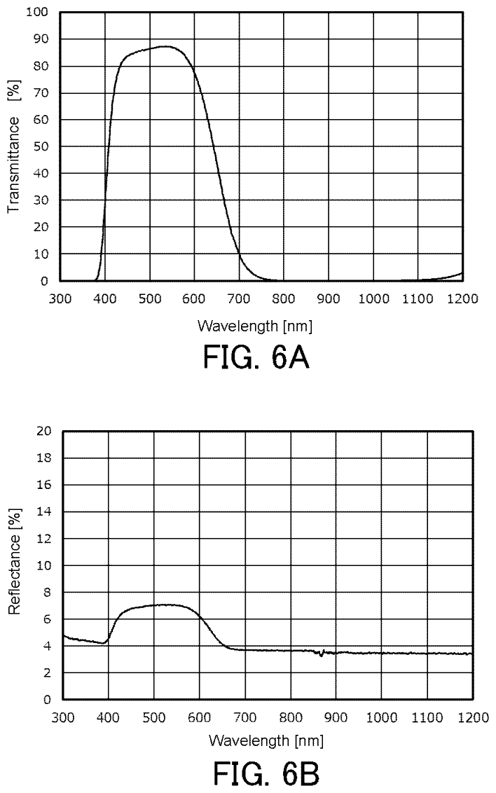

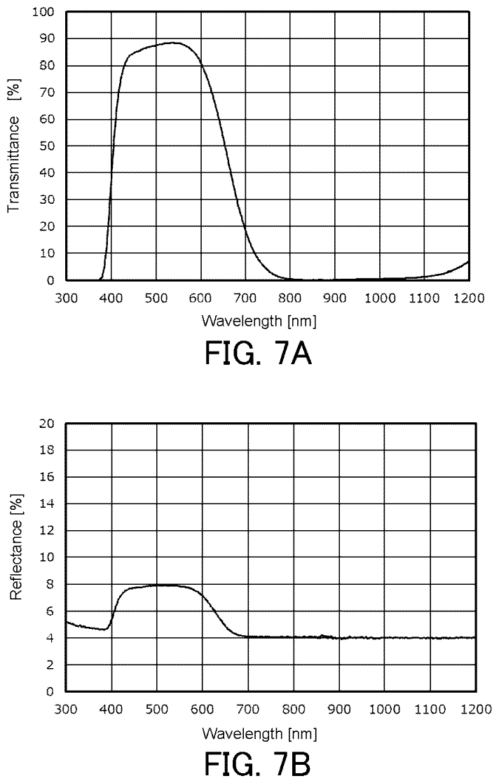

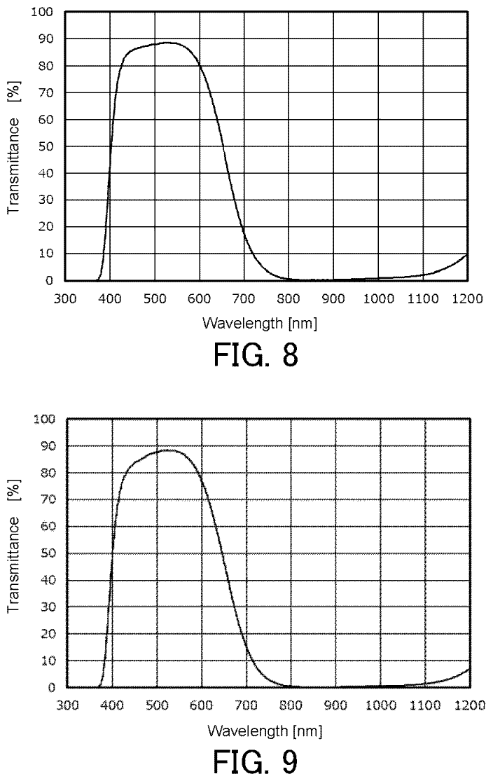

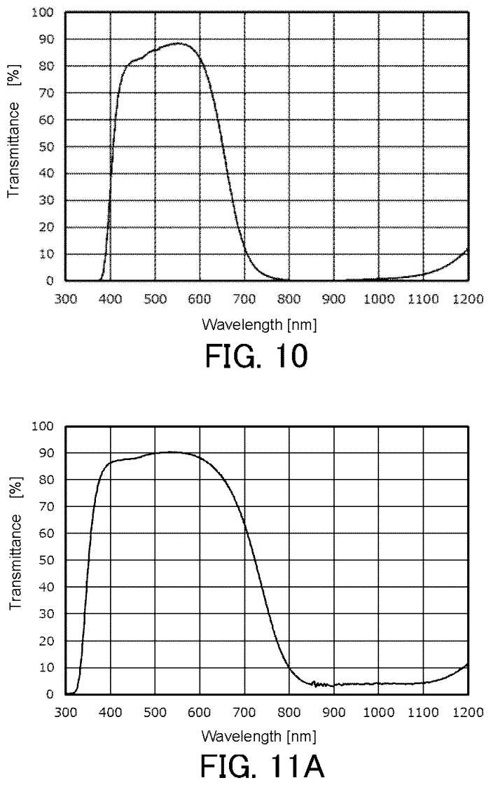

Light absorbers according to Examples 2 to 12 were produced in the same manner and under the same conditions as in Example 1, except that necessary compounds and the addition amounts thereof were changed as shown in Table 1A. Moreover, light absorbers according to Examples 13 and 14 were produced in the same manner and under the same conditions as in Example 1, except that necessary compounds and the addition amounts thereof were changed as shown in Table 1B. Tables 2 and 3 show the measurement or calculation results for property values of each light absorber. FIG. 6A and FIG. 6B respectively show a transmission spectrum and a reflection spectrum of the light absorber according to Example 2. FIG. 7A and FIG. 7B respectively show a transmission spectrum and a reflection spectrum of the light absorber according to Example 3. FIG. 8 shows a transmission spectrum of the light absorber according to Example 8. FIG. 9 shows a transmission spectrum of the light absorber according to Example 13. FIG. 10 shows a transmission spectrum of the light absorber according to Example 14.

### Example 15

An amount of 0.1 g of an anti-smudge surface coating agent (manufactured by DAIKIN INDUSTRIES, LTD.; product name: OPTOOL DSX; concentration of active ingredient: 20 mass %) and 19.9 g of a hydrofluoroether-containing solution (manufactured by 3M Company; product name: Novec 7100) were mixed and then stirred for five minutes to prepare a fluorine treatment agent (concentration of active ingredient: 0.1 mass %). This fluorine treatment agent was applied to one principal surface of a borosilicate glass substrate (manufactured by SCHOTT AG; product name: D263 T eco) having dimensions of 76 mm×76 mm×0.21 mm. The glass substrate was left at room temperature for 24 hours to dry the coating film made of the fluorine treatment agent, and the glass surface was then wiped lightly with a dust-free cloth impregnated with Novec 7100 to remove an excess of the fluorine treatment agent. A fluorine-treated substrate was thus produced.

A light-absorbing composition according to Example 15 was produced in the same manner and under the same conditions as in Example 1, except that necessary compounds and the addition amounts thereof were changed as shown in Table 1. A light absorber was formed on the above fluorine-treated substrate in the same manner as in Example 1, except that the light-absorbing composition according to Example 15 was used instead of the light-absorbing composition according to Example 1 and that the above fluorine-treated substrate was used instead of the substrate as used in Example 1. Next, this light absorber was peeled off the fluorine-treated substrate to give a film-shaped light absorber according to Example 15, which was used as an optical filter according to Example 15.

Tables 2 and 3 show the measurement or calculation results for property values of the optical filter according to Example 15.

### Example 16

An amount of 4.500 g of copper acetate monohydrate and 240 g of tetrahydrofuran (THF) were mixed, and the mixture was stirred for three hours to obtain a copper acetate solution. To the obtained copper acetate solution was then added 2.400 g of PLYSURF A208N (manufactured by DKS Co., Ltd.) which is a phosphoric acid ester compound, and the mixture was stirred for 30 minutes to obtain a solution (16-A). An amount of 40 g of THF was added to 2.800 g of n-butylphosphonic acid, and the resulting mixture was stirred for 30 minutes to obtain a solution (16-B). The solutions (16-A) and (16-B) were mixed and then stirred for one minute to obtain a solution (16-C). To the solution (16-C) was then added 120 g of toluene, and the mixture was stirred at room temperature for one minute to obtain a solution (16-D). The solution (16-D) was put in a flask and subjected to solvent removal using a rotary evaporator (manufactured by Tokyo Rikakikai Co., Ltd.; product code: N-1110SF) under heating by means of an oil bath (manufactured by Tokyo Rikakikai Co., Ltd.; product code: OSB-2100). The temperature of the oil bath was controlled to 105° C. The solution having undergone the solvent removal was collected from the flask. A liquid composition (16-E) in which a light-absorbing compound including a phosphonic acid and a copper component was dispersed was obtained in this manner.

An amount of 7.54 g of a silicone resin (manufactured by Shin-Etsu Chemical Co., Ltd.; product name: KR-300), 0.18 g of a catalyst (manufactured by Shin-Etsu Chemical Co., Ltd.; product name: CAT-AC), 9.74 g of methyltriethoxysilane (manufactured by Shin-Etsu Chemical Co., Ltd.; product name: KBE-13) as a trifunctional alkoxysilane, 5.68 g of a tetraethoxysilane (manufactured by KISHIDA CHEMICAL Co., Ltd.; special grade) as a tetrafunctional alkoxysilane, and 5.70 g of dimethyldiethoxysilane (DMDES) (manufactured by Shin-Etsu Chemical Co., Ltd.; product name: KBE-22) as a bifunctional alkoxysilane were mixed and then stirred for 30 minutes to obtain a thus-prepared liquid curable resin (16-F). Then, the above liquid composition (16-E) and the liquid curable resin (16-F) were mixed and then stirred for 30 minutes to produce a composition (16-G) for light-absorbing film.

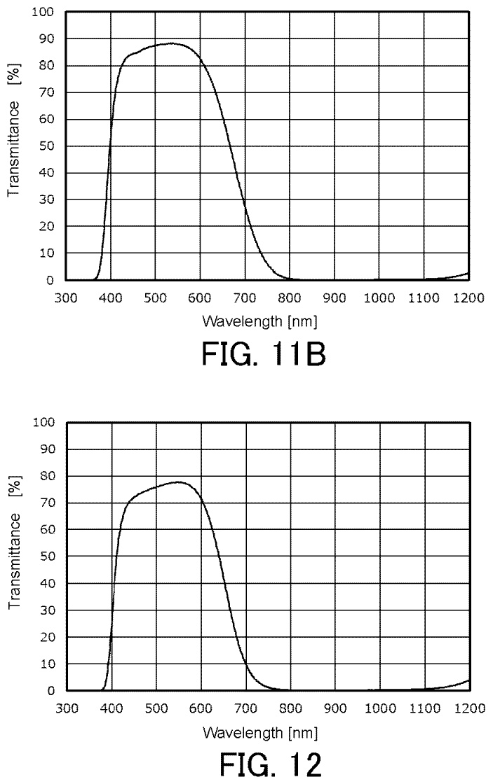

The composition (16-G) for light-absorbing film was applied with a dispenser to an 80 mm×80 mm region at a central portion of a fluorine-treated substrate produced in the same manner as in Example 15 to form a coating film. After the coating film was sufficiently dried at room temperature, the substrate and the coating film were put in an oven and heated sufficiently from room temperature to 85° C. to sufficiently carry out a reaction of the alkoxysilanes and evaporate the organic solvent in the composition (16-G) for light-absorbing film. After that, the coating film was left in an environment at a temperature of 85° C. and a relative humidity of 85% for additional 24 hours for post curing, and the reaction was completed. A light absorber was thus formed on the fluorine-treated substrate. Then, the light absorber was peeled off the fluorine-treated substrate to obtain a film-shaped light-absorbing-type substrate (16-H). FIG. 11A shows a transmission spectrum of the light-absorbing-type substrate (16-H). Additionally, Tables 2 to 4 show property values obtainable from this transmission spectrum and the thickness of the film-shaped light-absorbing-type substrate (16-H).

A light-absorbing composition according to Example 16 was prepared in the same manner and under the same conditions as in Example 1, except that necessary compounds and the addition amounts thereof were changed as shown in Table 1. An optical filter according to Example 16 including two light-absorbing layers was produced in the same manner and under the same conditions as in Example 1, except that the light-absorbing composition according to Example 16 was used instead of the light-absorbing composition according to Example 1 and that the light-absorbing-type substrate (16-H) was used as a substrate. FIG. 11B shows a transmission spectrum of the optical filter according to Example 16. Additionally, Tables 2 and 3 show the measurement or calculation results for property values of the optical filter according to Example 16.

### Comparative Examples 1 to 3

Light absorbers according to Comparative Examples 1 to 3 were produced in the same manner and under the same conditions as in Example 1, except that necessary compounds and the addition amounts thereof were changed as shown in Table 1. FIG. 12 shows a transmission spectrum of the optical filter according to Comparative Example 3. Tables 2 and 3 show the measurement or calculation results for measurable or calculable property values of each of the light absorbers according to Comparative Examples 1 to 3.

The light-absorbing composition according to Comparative Example 1 became notably cloudy, and a transparent optical filter was unable to be produced. It is inferred that in Comparative Example 1, the number of carbon atoms in an alkyl group directly bonded to a silicon atom was so low, namely 6, in the added trifunctional alkoxysilane that an aggregation reduction effect of a generated copper phosphonate compound was insufficient. In Comparative Example 2 where the addition amount of the same trifunctional alkoxysilane was larger, notable cloudiness still occurred. As for Comparative Example 3 where the addition amount of the same trifunctional silane was much larger, an optical filter was successfully produced. However, as shown in FIG. 12, the optical filter according to Comparative Example 3 has a low transmittance in the visible region, and the light absorber of the optical filter according to Comparative Example 3 has a thickness of 157 μm. In addition, the light absorber according to Comparative Example 3 has a very high haze, namely 12.96, and an optical filter having favorable properties was unable to be obtained. These results indicate that when the number of carbon atoms in an alkyl group of a trifunctional linear alkylsilane is less than 10, a sufficient aggregation reduction effect of a copper phosphonate is unable to be achieved and it is difficult to produce an optical filter having favorable optical properties.

### Example 17

### (Production of Liquid Precursor for Antireflection Film Formation)

An amount of 0.87 g of tetraethoxysilane (TEOS) being a tetrafunctional silane, 1.33 g of methyltriethoxysilane (MTES) being a trifunctional silane, 0.80 g of 0.3 weight % formic acid, 3.70 g of a hollow-silica-particle-including sol (manufactured by JGC Catalyst and Chemicals Ltd.; product name: THRULYA 4110; silica solids: approx. 25 weight %), and 27.3 g of ethanol were mixed, and were reacted at 30° C. for one hour and then at 35° C. for two hours to produce a liquid precursor A for formation of antireflection film (hereinafter referred to as “liquid composition A for antireflection film formation”).

### (Production of Optical Filter Including Antireflection Film)

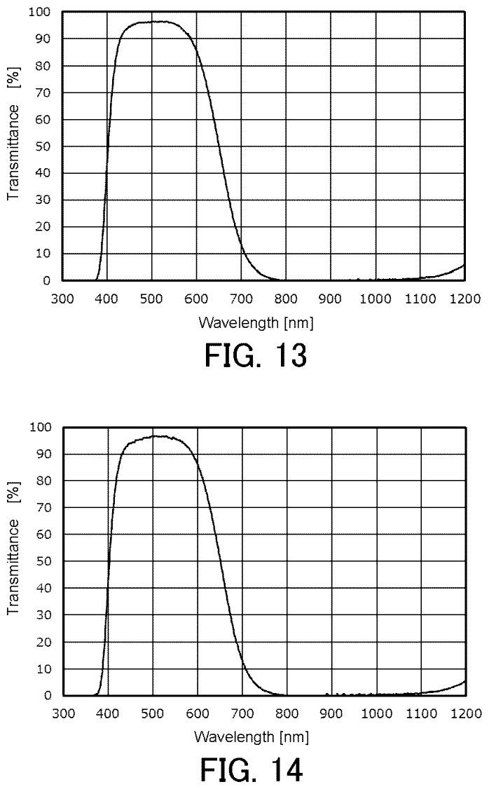

A liquid composition A for antireflection film formation was applied to one surface of an optical filter produced under the same conditions and in the same manner as in Example 15. An application amount and application conditions were adjusted so that the film thickness would be 120 nm after drying and curing. A spin coater was used for the application, and a rotation speed and a rotation time were also adjusted. The optical filter having the liquid composition A for antireflection film formation on the one surface was left to stand still for approximately one minute for initial drying. Furthermore, the liquid composition A for antireflection film formation was also applied to the other surface of the optical filter under the same conditions and in the same manner. The optical filter having the composition A having undergone the initial drying as described above on each surface was left to stand still for one hour in an oven heated at an internal temperature of 85° C. for reaction and solidification of the composition. An optical filter according to Example 17 was produced in this manner. This optical filter included an antireflection film on each side thereof. FIG. 13 shows a transmission spectrum of the optical filter according to Example 17. Table 5 shows property values and calculated values based on the transmission spectrum. Table 6 shows values each determined by dividing an optical density (OD) at a wavelength λ by the thickness of the light absorber.

### Example 18

### (Production of Liquid Precursor for Antireflection Film Formation)

An amount of 0.65 g of tetraethoxysilane (TEOS), 1.50 g of methyltriethoxysilane (MTES), 0.80 g of 0.3 weight % formic acid, and 27.3 g of ethanol were mixed, and were reacted at 30° C. for one hour and then at 35° C. for two hours. A composition B for antireflection film formation was produced in this manner.

### (Production of Optical Filter Including Antireflection Film)

A liquid composition B for antireflection film formation was applied to one surface of an optical filter produced under the same conditions and in the same manner as in Example 15. An application amount and application conditions were adjusted so that the film thickness would be 250 nm after drying and curing. A spin coater was used for the application, and a rotation speed and a rotation time were also adjusted. The optical filter having the liquid composition B for antireflection film formation on the one surface was left to stand still for approximately one minute for initial drying. Furthermore, the liquid composition B for antireflection film formation was also applied to the other surface of the optical filter under the same conditions and in the same manner. The optical filter having the composition B having undergone the initial drying as described above on each surface was left to stand still for one hour in an oven heated at an internal temperature of 85° C. for reaction and solidification of the composition. Next, the liquid composition A for antireflection film formation was applied to one surface of the optical filter including, on each side thereof, the layer formed by the solidification of the composition B for antireflection film formation. An application amount and application conditions were adjusted so that the film thickness would be 90 nm after drying and curing. A spin coater was used for the application, and a rotation speed and a rotation time were also adjusted. The optical filter having the liquid composition A for antireflection film formation on the one surface was left to stand still for approximately one minute for initial drying. Furthermore, the liquid composition A for antireflection film formation was also applied to the other surface of the optical filter under the same conditions and in the same manner. The optical filter having the composition A having undergone the initial drying as described above on each surface was left to stand still for one hour in an oven heated at an internal temperature of 85° C. for reaction and solidification of the composition. An optical filter according to Example 18 was produced in this manner. This optical filter included an antireflection film on each side thereof. FIG. 14 shows a transmission spectrum of the optical filter according to Example 18. Table 5 shows property values and calculated values based on the transmission spectrum. Table 6 shows values each determined by dividing an optical density (OD) at a wavelength λ by the thickness of the light absorber.

TABLE 1A

| | Light-absorbing composition | | | | | | |
|---|---|---|---|---|---|---|---|
| | | Phosphonic acid | | | | | |
| | | Aryl-based phosphonic acid | | | | | |
| | Copper | Phenyl- | 4-Bromophenyl- | 4-Fluorophenyl- | 4-Iodephenyl- | Alkyl-based phosphonic acid | |
| | acetate | phosphonic | phosphonic | phosphonic | phosphonic | Butylphosphonic | Ethylphosphonic |
| | monohydrate | acid | acid | acid | acid | acid | acid |
| | [g] | [g] | [g] | [g] | [g] | [g] | [g] |
| Ex. 1 | 4.500 | 0.610 | 3.660 | 0 | 0 | 0.758 | 0 |
| Ex. 2 | 4.500 | 0.610 | 3.660 | 0 | 0 | 0.758 | 0 |
| Ex. 3 | 4.500 | 0.610 | 3.660 | 0 | 0 | 0.758 | 0 |
| Ex. 4 | 4.500 | 0.610 | 3.660 | 0 | 0 | 0.758 | 0 |
| Ex. 5 | 4.500 | 0.610 | 3.660 | 0 | 0 | 0.758 | 0 |
| Ex. 6 | 4.500 | 0.610 | 3.660 | 0 | 0 | 0.758 | 0 |
| Ex. 7 | 4.500 | 0.610 | 3.660 | 0 | 0 | 0.758 | 0 |
| Ex. 8 | 4.500 | 0.610 | 3.660 | 0 | 0 | 0.758 | 0 |
| Ex. 9 | 4.500 | 0.610 | 0 | 1.360 | 2.193 | 0.758 | 0 |
| Ex. 10 | 4.500 | 0.610 | 3.660 | 0 | 0 | 0 | 0.604 |
| Ex. 11 | 4.500 | 0.610 | 3.660 | 0 | 0 | 0.758 | 0 |
| Ex. 12 | 4.500 | 0.610 | 3.660 | 0 | 0 | 0.758 | 0 |
| Ex. 15 | 4.500 | 0.610 | 3.660 | 0 | 0 | 0.758 | 0 |
| Ex. 16 | 4.500 | 0.610 | 3.660 | 0 | 0 | 0.758 | 0 |
| Comp. | 4.500 | 0.610 | 3.660 | 0 | 0 | 0.758 | 0 |
| Ex. 1 | | | | | | | |
| Comp. | 4.500 | 0.610 | 3.660 | 0 | 0 | 0.758 | 0 |
| Ex. 2 | | | | | | | |
| Comp. | 4.500 | 0.610 | 3.660 | 0 | 0 | 0.758 | 0 |
| Ex. 3 | | | | | | | |

| | Light-absorbing composition | | | | | | |
|---|---|---|---|---|---|---|---|
| | Alkoxysilane | | | | | | |
| | | Trifunctional | | | | Bifunctional | Molar ratio of |
| | | <C6> | <C10> | <C16> | <C18> | <C18C1> | long-chain |
| | Tetrafunctional | N-hexyltri- | N-decyltri- | N-hexadecyltri- | N-octadecyltri- | N-octadecylmethyl- | alkylalkoxysilane |
| | Tetraethoxysilane | ethoxysilane | methoxysilane | methoxysilane | methoxysilane | diethoxysilane | content to copper |
| | [g] | [g] | [g] | [g] | [g] | [g] | component content |
| Ex. 1 | 2.78 | 0 | 0 | 4.00 | 0 | 0 | 0.51 |
| Ex. 2 | 2.78 | 0 | 4.34 | 0 | 0 | 0 | 0.73 |
| Ex. 3 | 2.78 | 5.79 | 0 | 4.00 | 0 | 0 | 0.51 |
| Ex. 4 | 4.17 | 0 | 0 | 5.99 | 0 | 0 | 0.77 |
| Ex. 5 | 1.95 | 0 | 0 | 2.80 | 0 | 0 | 0.36 |
| Ex. 6 | 5.56 | 0 | 0 | 7.99 | 0 | 0 | 1.02 |
| Ex. 7 | 5.56 | 0 | 8.69 | 0 | 0 | 0 | 1.47 |
| Ex. 8 | 8.34 | 0 | 13.03 | 0 | 0 | 0 | 2.20 |
| Ex. 9 | 2.78 | 0 | 0 | 4.00 | 0 | 0 | 0.51 |
| Ex. 10 | 4.17 | 0 | 0 | 5.99 | 0 | 0 | 0.77 |
| Ex. 11 | 2.78 | 0 | 0 | 0 | 3.92 | 0 | 0.46 |
| Ex. 12 | 2.78 | 0 | 0 | 0 | 0 | 4.32 | 0.50 |
| Ex. 15 | 4.17 | 0 | 0 | 5.99 | 0 | 0 | 0.77 |
| Ex. 16 | 2.78 | 0 | 0 | 4.00 | 0 | 0 | 0.51 |
| Comp. | 2.78 | 5.79 | 0 | 0 | 0 | 0 | 0 |
| Ex. 1 | | | | | | | |
| Comp. | 5.56 | 11.58 | 0 | 0 | 0 | 0 | 0 |
| Ex. 2 | | | | | | | |
| Comp. | 13.9 | 28.96 | 0 | 0 | 0 | 0 | 0 |
| Ex. 3 | | | | | | | |

TABLE 1B

| | Light-absorbing composition | | | | | | |
|---|---|---|---|---|---|---|---|
| | | Phosphonic acid | | | | | |
| | | Aryl-based phosphonic acid | | | | | |
| | Copper | Phenyl- | 4-Bromophenyl- | 4-Fluorophenyl- | 4-Iodephenyl- | Alkyl-based phosphonic acid | |
| | acetate | phosphonic | phosphonic | phosphonic | phosphonic | Butylphosphonic | Ethylphosphonic |
| | monohydrate | acid | acid | acid | acid | acid | acid |
| | [g] | [g] | [g] | [g] | [g] | [g] | [g] |
| Ex. 13 | 4.500 | 0.610 | 3.660 | 0 | 0 | 0.758 | 0 |
| Ex. 14 | 4.500 | 0.610 | 3.660 | 0 | 0 | 0.758 | 0 |

| | Light-absorbing composition | | | | |
|---|---|---|---|---|---|
| | Alkoxysilane | | | | |
| | | Trifunctional | | Bifunctional | Molar ratio of |
| | | <C11> | <C12> | <C18C1> | long-chain |
| | Tetrafunctional | 8-Glycidoxyoctyl- | 8-Methacryloxyoctyl- | N-octadecylmethyl- | alkylalkoxysilane |
| | Tetraethoxysilane | trimethoxysilane | trimethoxysilane | diethoxysilane | content to copper |
| | [g] | [g] | [g] | [g] | component content |
| Ex. 13 | 4.20 | 6.22 | 0 | 0 | 1.16 |
| Ex. 14 | 3.92 | 0 | 7.08 | 1.54 | 1.54 |

TABLE 2

Spectral properties
Transmission spectrum

| | | | | Wavelength | Wavelength |
|---|---|---|---|---|---|
| | Average | Average | Average | λ⁰_{UV} [nm] that | λ⁰_{IR} [nm] that |
| | transmittance | transmittance | transmittance | lies in range of | lies in range of |
| | T^{A}₃₀₀₋₃₈₀ [%] in | T^{A}₇₅₀₋₁₁₀₀ [%] in | T^{A}₄₆₀₋₆₀₀ [%] in | 350 nm to 460 | 600 nm to 700 |
| | range of 300 | range of 750 | range of 460 | nm and at which | nm and at which |
| | nm to 380 nm | nm to 1100 nm | nm to 600 nm | transmittance is 50% | transmittance is 50% |
| Ex. 1 | 0.05 | 0.22 | 85.17 | 408 | 646 |
| Ex. 2 | 0.02 | 0.14 | 85.37 | 408 | 643 |
| Ex. 3 | 0.10 | 0.67 | 86.77 | 405 | 655 |
| Ex. 4 | 0.05 | 0.47 | 87.06 | 406 | 654 |
| Ex. 5 | 0.10 | 0.8 | 86.38 | 404 | 659 |
| Ex. 6 | 0.12 | 0.99 | 87.94 | 403 | 659 |
| Ex. 7 | 0.07 | 0.44 | 86.75 | 405 | 649 |
| Ex. 8 | 0.16 | 0.91 | 86.92 | 403 | 653 |
| Ex. 9 | 0.05 | 0.22 | 85.17 | 408 | 646 |
| Ex. 10 | 0.05 | 0.47 | 87.06 | 406 | 654 |
| Ex. 11 | 0.53 | 0.68 | 84.34 | 409 | 646 |
| Ex. 12 | 0.01 | 0.31 | 84.59 | 411 | 637 |
| Ex. 13 | 0.31 | 0.64 | 86.01 | 401 | 646 |
| Ex. 14 | 0.05 | 0.70 | 86.29 | 406 | 651 |
| Ex. 15 | 0.05 | 0.47 | 87.06 | 406 | 654 |
| Ex. 16 | 0.73 | 0.55 | 86.75 | 398 | 667 |
| Comp. | — | — | — | — | — |
| Ex. 1 | | | | | |
| Comp. | — | — | — | — | — |
| Ex. 2 | | | | | |
| Comp. | 0.05 | 0.25 | 75.87 | 412 | 640 |
| Ex. 3 | | | | | |

Spectral properties
Reflection spectrum

| | Average | Average | | |
|---|---|---|---|---|
| | reflectance | reflectance | Reflectance | Reflectance |
| | R^{A}₄₅₀₋₅₅₀ [%] | R^{A}₇₀₀₋₁₀₀₀ [%] | at 350 nm | at 380 nm |
| | in range of | in range of | R₃₅₀ | R₃₈₀ |
| | 450 nm to 550 nm | 700 nm to 1000 nm | [%] | [%] |
| Ex. 1 | 7.67 | 3.99 | 4.68 | 4.54 |
| Ex. 2 | 6.89 | 3.57 | 4.41 | 4.23 |
| Ex. 3 | 7.89 | 4.06 | 4.77 | 4.64 |
| Ex. 4 | 7.59 | 3.83 | 4.67 | 4.53 |
| Ex. 5 | 7.26 | 3.61 | 4.52 | 4.36 |
| Ex. 6 | 6.95 | 3.76 | 4.56 | 4.4 |
| Ex. 7 | 6.79 | 3.81 | 4.4 | 4.19 |
| Ex. 8 | 6.87 | 3.73 | 4.71 | 4.54 |
| Ex. 9 | 6.84 | 3.99 | 4.49 | 4.38 |
| Ex. 10 | 6.65 | 3.9 | 4.37 | 4.22 |
| Ex. 11 | 7.74 | 3.86 | 4.76 | 4.6 |
| Ex. 12 | 7.65 | 4.04 | 4.56 | 4.36 |
| Ex. 13 | 6.43 | 3.62 | 4.50 | 4.21 |
| Ex. 14 | 7.22 | 3.80 | 4.60 | 4.45 |
| Ex. 15 | 7.42 | 3.96 | 4.68 | 4.56 |
| Ex. 16 | 7.43 | 3.87 | 4.64 | 4.42 |
| Comp. | — | — | — | — |
| Ex. 1 | | | | |
| Comp. | — | — | — | — |
| Ex. 2 | | | | |
| Comp. | 7.86 | 4.02 | 4.29 | 4.18 |
| Ex. 3 | | | | |

| | | Structure of optical filter | | |
|---|---|---|---|---|
| | | Light absorber | Substrate | |
| | | Thickness of | | Thickness of |
| | Haze | light absorber | Type/ | substrate |
| | [%] | [μm] | Material | [μm] |
| Ex. 1 | 0.19 | 97 | Glass | 210 |
| Ex. 2 | 0.15 | 100 | Glass | 210 |
| Ex. 3 | 0.16 | 110 | Glass | 210 |
| Ex. 4 | 0.15 | 110 | Glass | 210 |
| Ex. 5 | 0.10 | 69 | Glass | 210 |
| Ex. 6 | 0.15 | 110 | Glass | 210 |
| Ex. 7 | 0.15 | 108 | Glass | 210 |
| Ex. 8 | 0.18 | 110 | Glass | 210 |
| Ex. 9 | 0.17 | 107 | Glass | 210 |
| Ex. 10 | 0.17 | 100 | Glass | 210 |
| Ex. 11 | 0.17 | 94 | Glass | 210 |
| Ex. 12 | 0.19 | 99 | Glass | 210 |
| Ex. 13 | 0.16 | 100 | Glass | 210 |
| Ex. 14 | 0.16 | 109 | Glass | 210 |
| Ex. 15 | 0.15 | 110 | N/A | — |
| Ex. 16 | 0.18 | 47 | Light- | 50 |
| | | | absorbing | |
| | | | film | |
| Comp. | — | — | — | — |
| Ex. 1 | | | | |
| Comp. | — | — | — | — |
| Ex. 2 | | | | |
| Comp. | 12.69 | 157 | Glass | 210 |
| Ex. 3 | | | | |

TABLE 3

| | η₃₈₀ | η₇₅₀ | η₈₀₀ | η₉₀₀ | η₁₀₀₀ | η₁₁₀₀ |
|---|---|---|---|---|---|---|
| | [/μm] | [/μm] | [/μm] | [/μm] | [/μm] | [/μm] |
| Ex. 1 | 0.022 | 0.019 | 0.030 | 0.028 | 0.028 | 0.024 |
| Ex. 2 | 0.023 | 0.020 | 0.031 | 0.033 | 0.029 | 0.025 |
| Ex. 3 | 0.016 | 0.013 | 0.021 | 0.023 | 0.020 | 0.017 |
| Ex. 4 | 0.017 | 0.014 | 0.022 | 0.026 | 0.022 | 0.019 |
| Ex. 5 | 0.025 | 0.020 | 0.032 | 0.037 | 0.031 | 0.026 |
| Ex. 6 | 0.015 | 0.012 | 0.019 | 0.021 | 0.019 | 0.016 |
| Ex. 7 | 0.017 | 0.015 | 0.024 | 0.026 | 0.022 | 0.018 |
| Ex. 8 | 0.014 | 0.013 | 0.020 | 0.022 | 0.019 | 0.015 |
| Ex. 9 | 0.019 | 0.016 | 0.025 | 0.029 | 0.025 | 0.021 |
| Ex. 10 | 0.018 | 0.014 | 0.022 | 0.027 | 0.022 | 0.019 |
| Ex. 11 | 0.021 | 0.019 | 0.025 | 0.021 | 0.021 | 0.022 |
| Ex. 12 | 0.025 | 0.024 | 0.033 | 0.034 | 0.025 | 0.017 |
| Ex. 13 | 0.013 | 0.015 | 0.023 | 0.027 | 0.022 | 0.019 |
| Ex. 14 | 0.018 | 0.016 | 0.023 | 0.025 | 0.029 | 0.015 |
| Ex. 15 | 0.017 | 0.014 | 0.022 | 0.026 | 0.022 | 0.019 |
| Ex. 16 | 0.020 | 0.017 | 0.027 | 0.031 | 0.026 | 0.022 |
| Comp. | — | — | — | — | — | — |
| Ex. 1 | | | | | | |
| Comp. | — | — | — | — | — | — |
| Ex. 2 | | | | | | |
| Comp. | 0.014 | 0.012 | 0.018 | 0.019 | 0.017 | 0.014 |
| Ex. 3 | | | | | | |

TABLE 4

| | Spectral properties | | | | |
|---|---|---|---|---|---|
| | Transmission spectrum | | | | |
| | | | | Wavelength | Wavelength |
| | | | | λ⁰_{UV} [nm] that | λ⁰_{IR} [nm] that |
| | Average | Average | Average | lies in range | lies in range |
| | transmittance | transmittance | transmittance | of 350 nm to | of 600 nm to |
| | T^{A}₃₀₀₋₃₈₀ [%] | T^{A}₇₅₀₋₁₁₀₀ | T^{A}₄₆₀₋₆₀₀ [%] | 460 nm and | 700 nm and |
| | in range of | [%] in range | in range of | at which | at which |
| | 300 nm to | of 750 nm to | 460 nm to | transmittance | transmittance |
| | 380 nm | 1100 nm | 600 nm | is 50% | is 50% |
| Ex. 14 | 33.16 | 6.48 | 89.65 | 351 | 723 |
| (Light-absorbing | | | | | |
| substrate) | | | | | |

TABLE 5

| | Spectral properties | | | | | | | | |
|---|---|---|---|---|---|---|---|---|---|
| | Transmission spectrum | | | | | | Structure of optical filter | | |
| | Average | Average | Average | Wavelength | Wavelength | | Light | | |
| | transmittance | transmittance | transmittance | λ₂⁰_{UV} [nm] that | λ₂⁰_{IR} [nm] that | | absorber | Antireflection film | |
| | T₂^{A}₃₀₀₋₃₈₀ [%] | T₂^{A}₇₅₀₋₁₁₀₀ [%] | T₂^{A}₄₆₀₋₆₀₀ [%] | lies in range of | lies in range of | | Thickness | Thickness | Thickness |
| | in range of | in range of | in range of | 350 nm to 460 | 600 nm to 700 | | of light | of first | of second |
| | 300 nm to | 750 nm to | 460 nm to | nm and at which | nm and at which | Haze | absorber | layer | layer |
| | 380 nm | 1100 nm | 600 nm | transmittance is 50% | transmittance is 50% | [%] | [μm] | [nm] | [nm] |
| Ex. 17 | 0.09 | 0.32 | 94.60 | 403 | 650 | 0.15 | 110 | 120 | — |
| Ex. 18 | 0.12 | 0.35 | 94.75 | 403 | 651 | 0.15 | 110 | 250 | 90 |

TABLE 6

| | η₂₋₃₈₀ | η₂₋₇₅₀ | η₂₋₈₀₀ | η₂₋₉₀₀ | η₂₋₁₀₀₀ | η₂₋₁₁₀₀ |
|---|---|---|---|---|---|---|
| | [/μm] | [/μm] | [/μm] | [/μm] | [/μm] | [/μm] |
| Ex. 17 | 0.015 | 0.016 | 0.028 | 0.026 | 0.021 | 0.018 |
| Ex. 18 | 0.016 | 0.016 | 0.027 | 0.027 | 0.020 | 0.018 |

1. A light-absorbing composition comprising:
at least one selected from the group consisting of an alkoxysilane including a group having 10 or more carbon atoms, a hydrolysate of the alkoxysilane, and a polymerization product of a hydrolysate of the alkoxysilane; and
a light-absorbing compound.

2. The light-absorbing composition according to claim 1, wherein the light-absorbing compound includes a phosphoric acid compound and a copper component.

3. The light-absorbing composition according to claim 1, wherein the light-absorbing compound includes a phosphonic acid and a copper component.

4. The light-absorbing composition according to claim 1, wherein a light absorber being a solidified product of the light-absorbing composition satisfies the following requirements (i) and (ii):
(i) 0.009≤η₃₈₀ and 0.008≤η₇₅₀, where a value determined by dividing an optical density OD at a wavelength λ by a thickness of the light absorber is expressed as η_{λ}[μm⁻¹]; and
(ii) 80%≤T^{A}₄₆₀₋₆₀₀, where T^{A}₄₆₀₋₆₀₀ is an average transmittance in a wavelength range of 460 nm to 600 nm.

5. (canceled)

6. A light absorber
having an average T^{A}₄₆₀₋₆₀₀ of 80% or more, where the average T^{A}₄₆₀₋₆₀₀ is an average transmittance in a wavelength range of 460 nm to 600 nm in a transmission spectrum obtained by allowing light to be incident on the light absorber at an incident angle of 0°, and
satisfying requirements 0.009≤η₃₈₀ and 0.008≤η₇₅₀, where a value determined by dividing an optical density OD of the light absorber at a wavelength λ by a thickness of the light absorber is expressed as η_{λ}[μm⁻¹].

7. The light absorber according to claim 6, having a haze less than 0.2%.

8. The light absorber according to claim 6, wherein
an average T^{A}₃₀₀₋₃₈₀ and an average T^{A}₇₅₀₋₁₁₀₀ respectively satisfy requirements T^{A}₃₀₀₋₃₈₀≤1.5% and T^{A}₇₅₀₋₁₁₀₀≤2.0%, where
the average T^{A}₃₀₀₋₃₈₀ is an average transmittance in a wavelength range of 300 nm to 380 nm in the transmission spectrum, and
the average T^{A}₇₅₀₋₁₁₀₀ is an average transmittance in a wavelength range of 750 nm to 1100 nm in the transmission spectrum.

9. An optical filter comprising the light absorber according to claim 6.

10. The optical filter according to claim 9, comprising:
the light absorber; and
an antireflection film provided on a surface of the light absorber.

11. The optical filter according to claim 10, wherein the antireflection film includes one layer or two or more layers selected from the group consisting of the following layers (a), (b1), (b2), and (c):
(a) a layer including silsesquioxane and silica;
(b1) a layer including silsesquioxane, silica, and a hollow particle;
(b2) a layer including silsesquioxane, silica, and a solid particle; and
(c) a layer including at least one material selected from the group consisting of SiO₂, TiO₂, Ta₂O₃, SnO₂, In₂O₃, Nb₂O₅, Si₃N₄, TiNₓ, and MgF₂.

12. The optical filter according to claim 11, wherein the layer (b1) includes a hollow particle having a refractive index of 1.02 to 1.50.

13. The optical filter according to claim 11, wherein the layer (c) is composed of one layer or two or more layers formed of different materials.

14. The optical filter according to claim 11, wherein
the antireflection film includes the layer (b1) and the layer (b2), and
the layer (b2) has a higher refractive index than that of the layer (b1).

15. The optical filter according to claim 11, wherein the layer (b1) includes a hollow particle having a refractive index of 1.02 to 1.50.

16. The optical filter according to claim 11, wherein the layer (b2) includes a solid particle having a refractive index of 1.25 to 2.75.

17. (canceled)

18. An imaging apparatus comprising the light absorber according to claim 6.

19-22. (canceled)

23. An optical filter comprising:
a light absorber; and
an antireflection film provided on a surface of the light absorber, wherein
the optical filter satisfies the following requirements (I) and (II):
(I) 0.009≤η₂₋₃₈₀ and 0.008≤η₂₋₇₅₀, where a value determined by dividing an optical density OD at a wavelength λ by a thickness of the light absorber is expressed as η_{2-λ}[μm⁻¹]; and
(II) 90%≤T₂^{A}₄₆₀₋₆₀₀, where T₂^{A}₄₆₀₋₆₀₀ is an average transmittance in a wavelength range of 460 nm to 600 nm.

24. The optical filter according to claim 23, satisfying 0.020≤η₂₋₉₀₀ and 0.013≤η₂₋₁₁₀₀.

25. The optical filter according to claim 23, satisfying:
T₂^{A}₃₀₀₋₃₈₀≤1.5% and T₂^{A}₇₅₀₋₁₁₀₀≤2.0%, where T₂^{A}₃₀₀₋₃₈₀ is an average transmittance in a wavelength range of 300 nm to 380 nm and T₂^{A}₇₅₀₋₁₁₀₀ is an average transmittance in a wavelength range of 750 nm to 1100 nm; and
390 nm≤λ₂⁰_{UV}≤450 nm and 600 nm≤λ₂⁰_{IR}≤680 nm, where λ₂⁰_{UV} is a second ultraviolet cut-off wavelength that lies in a wavelength range of 350 nm to 460 nm and at which a transmittance is 50% and λ₂⁰ is a second infrared cut-off wavelength that lies in a wavelength range of 600 nm to 700 nm and at which a transmittance is 50%.

26. The optical filter according to claim 23, wherein the antireflection film includes a layer including silsesquioxane and silica.
